(19) United States
(12) Patent Application Publication
(10) Pub. No.: US 2004/0019466 A1
(43) Pub. Date: Jan. 29, 2004

(54) Microarray performance management system

(76) Inventors: James M. Minor, Los Altos, CA (US); Mika Illouz, Palo Alto, CA (US); George A. Watson, Los Altos, CA (US); Robert D. Dickinson, Redwood City, CA (US)

Correspondence Address: AGILENT TECHNOLOGIES, INC., INTELLECTUAL PROPERTY ADMINISTRATION, LEGAL DEPT., P.O. BOX 7599, M/S DL429, LOVELAND, CO, 80537-0599, US

(21) Appl. No.: 10/422,570

(22) Filed: Apr. 23, 2003

Related U.S. Application Data
(60) Provisional application No. 60/375,251, filed on Apr. 23, 2002.

(51) Int. Cl. H03F 1/26; H04B 15/00

(52) U.S. Cl. 702/190

(57) ABSTRACT

Systems, methods and computer readable media for evaluating profiles of multi-variable data values. Systems, methods and computer readable media for removing nuisance distortions from data to provide “cleaner”, more reliable data.

### CROSS-REFERENCE

This application claims the benefit of U.S. Provisional Application No. 60/375,251, filed Apr. 23, 2002, and titled “Microarray Performance Management System”, which application is incorporated herein by reference, in its entirety.

### FIELD OF THE INVENTION

The present invention relates to the processing of multivariable data to remove unwanted artifacts and noise, The present invention further relates to techniques for further processing such data to automatically classify and quality score the data after removing unwanted signal interference. More particularly, the present invention relates to interpretation of data from microarrays containing biological information.

### BACKGROUND OF THE INVENTION

Researchers use experimental data obtained from microarrays and other similar research test equipment to cure diseases, develop medical treatments, understand biological phenomena, and perform other tasks relating to the analysis of such data. However, the conversion of useful results from this raw data is restricted by physical limitations of, e.g., the nature of the tests and the testing equipment. All biological measurement systems leave their fingerprint on the data they measure, distorting the content of the data, and thereby influencing the results of the desired analysis. For example, systematic biases can distort microarray analysis results and thus conceal important biological effects sought by the researchers. Biased data can cause a variety of analysis problems, including signal compression, aberrant graphs, and significant distortions in estimates of differential expression. Types of systematic biases include gradient effects, differences in signal response between channels (e.g., for a two channel system), variations in hybridization or sample preparation, pen shifts and subarray variation, and differences in RNA inputs.

Gradient effects are those in which there is a pattern of expression signal intensity which corresponds with specific physical locations within the chip and which are characterized by a smooth change in the expression values from one end of the chip to another. This can be caused by variations in chip design, manufacturing, and/or hybridization procedures. FIG. 1 shows an example of distortion caused by gradient effects, where it can be observed that the signal intensity shows a gradually increasing pattern moving from a first edge 100 (see signals corresponding at 200) to a second edge 102 (corresponding signals 202) of the chip.

In dual-channel systems, it is well known that the two dyes do not always perform equally efficiently, for equivalent RNA concentrations, uniformly across the whole microarray. In particular, the red channel often demonstrates higher signal intensity than the green channel at higher RNA abundances.

Variations in hybridization and sample preparations can cause warpage to occur in the expression values in microarrays. This can prevent comparative analysis across batches of arrays and further distort analysis results.

Subarray variations are forms of systematic biases in which different probe subsets within the chip demonstrate significantly different performance characteristics. In particular, there may be multiple subsets that have different average signal intensities. This is sometimes referred to as “blocking” within the resultant array pattern, due to the visual, block-like appearance resultant from the probe subsets. These subarray variations may be related to individual pens/nozzles or other manufacturing discreteness or boundaries, as well as other process details.

Device distortions aside, another problem facing researchers is the task of quality control and assessment of microarray measurements. Because they are performed manually, these tasks are time-consuming, expensive, and prone to error.

Because of the large amount of data involved, inspection and review of microarray results is complex and tedious, requiring knowledge of multiple microarray technology platforms and manufacturing techniques. Therefore, it is often difficult to find and retain qualified personnel for such positions, which further increases the associated cost. Review of microarray data is also time-consuming and costly because, under manual inspection, 40%-50% of all hybridized microarrays typically require at least one interpretation of the acceptability of the results. Thorough inspection at these levels becomes cost prohibitive as the number of hybridizations performed per week increases into the hundreds or thousands.

In addition, manual review of microarray data is imprecise and inconsistent. Agreement between research scientists is frequently less than 60%. To avoid systematic shifts in an inspector's judgment over time, inspectors must constantly be “re-calibrated” (i.e., re-trained) to their own previous judgments as well as to the judgments of others. Moreover, marginal cases are difficult to flag. As the volume of hybridizations increases, identification of marginal cases or close calls becomes difficult. These cases may require more detailed study or expert opinions to properly classify and quantify results. Lastly, heuristic thresholds are often set on quality control parameters. Thresholds on quality control parameters are frequently set independently for each parameter without statistical adjustment for the multiplicity of tests being performed. This leads to increased failure rates and increased costs.

### SUMMARY OF THE INVENTION

The present invention provides systems, methods and computer readable media for evaluating profiles of multi-variable data values, by training on a training set of profiles having been previously evaluated. From such training, the systems “learn” how to prospectively evaluate profiles having like categories of multi-variable data values, but which have not been previously evaluated. From the training set, the present invention determines a computer functional relationship between the training profiles and values assigned to the respective training profiles during the previous evaluation. The computer functional relationship may then be applied to one or more profiles which have not been previously evaluated to generate evaluation values for the one or more profiles which have not been previously evaluated, or any other profile or profiles not belonging to the training set.

In one example, the profiles of the training set and each of the profiles which have not been previously evaluated comprise data characterizing microarrays containing biological information. The profiles of multi-variable data may include metrics generated from analyzing signals generated from reading, scanning and/or processing the microarrays. Examples of such metrics include estimated parameters from de-trending, estimated parameters from de-warping, delta metrics, accuracy metrics, precision metrics, analytical sensitivity metrics, linearity metrics, dynamic and linear dynamic range metrics and statistical calibration metrics.

The training by the present invention may include de-trending the training set of profiles, de-warping the training set of profiles, and creation of metrics representative of the de-trended profiles and the de-warped profiles, respectively. Delta metrics, defined as the difference between the de-trended metrics and the de-warped metrics, may also be created.

The determination of a computer function relationship may be performed by use of an initial model (a simple model, such as Model Zero) and development of a complex model to determine the computer functional relationship. The complex model may be selected from various predictor-corrector models described herein.

The evaluation performed may be the automatic assignment of classification and quality scoring values to the previously uninspected, unclassified or unscored profiles, or other profiles not belonging to the training set.

In one example, a method of automatically classifying and quality scoring microarrays containing biological data is described to include training on a training set of microarrays having been previously classified and scored by one or more human inspectors; determining a computer functional relationship between the training set and classification and scoring values assigned to the respective training microarrays in the training set by the one or more human inspectors; and applying the computer functional relationship to one or more microarrays containing biological data and not belonging to the training set. For example, the microarrays not belonging to the training set may be microarrays which have not been previously classified or scored by a human inspector. The microarrays not belonging to the training set are automatically classified and scored based on the computer functional relationship.

The training may include de-trending each microarray in the training set; creating metrics representative of each microarray after de-trending; de-warping each microarray in the training set; creating metrics representative of each microarray after de-warping; and generating a profile for each microarray in the training set, wherein each profile contains the metrics after de-trending and de-warping.

The determination of a computer functional relationship may include applying an initial model (e.g., a simple model) and developing a complex model to determine the computer functional relationship between the profiles and the classification and quality scores having been previously assigned to the training set. Such application may include de-trending each microarray not belonging to the training set; creating metrics representative of each microarray not belonging to the training set; de-warping each microarray not belonging to the training set; creating metrics representative of each microarray not belonging to the training set, after de-warping; generating a profile for each microarray not belonging to the training set, wherein each profile contains the metrics after de-trending and de-warping; and applying the computer functional relationship to the profiles characterizing the arrays not belonging to the training set, to automatically classify and quality score the arrays not belonging to the training set.

Further disclosed are methods, systems and computer readable media for removing nuisance distortions from array data, which include systems, computer readable media or methods for inputting signals generated from reading an array containing biological data; applying at least one algorithm to the inputted signals to estimate and remove at least one nuisance distortion from the signals representing the array data; and outputting signals representative of the biological data after removal of at least one nuisance distortion.

Signals representative of the biological data are retained in the outputted signals.

Algorithms that may be applied include algorithms for de-trending, gradient analysis and filtering of the inputted signals; entering at least one blocking factor to remove blocking effects; employing response-surface methodology to approximate global gradient effects of the inputted data; harmonic model plus shift effects; second-order polynomial plus shift factors; use of statistical predictor methods using similarity transforms, such as SLS™, or that described in co-pending, commonly owned application serial no. optimizing de-trending by least squares regression or other method of regression; and/or de-warping.

Nuisance distortions that may be removed include array patterns, channel bias, build bias and some bio-distortions that misrepresent the data (e.g., non-random array probes).

These and other advantages and features of the invention will become apparent to those persons skilled in the art upon reading the details of the processes and systems, as more fully described below.

### BRIEF DESCRIPTION OF THE DRAWINGS

FIG. 1 is a graphical representation illustrating gradient effects imposed upon biological signal readings from a microarray, due to manufacturing imperfections in the production process.

FIG. 2 is a graphical representation illustrating blocking effects imposed upon biological signal readings, due to subarray variations, such as those caused by non-conformity of the pens, pens-shifting, etc.

FIG. 3 is a graph showing the expected ellipsoidal pattern when ln( test signal) generated from gene probes on a test array is plotted against ln(reference signal)) generated from gene probes on a reference array.

FIG. 4 shows a two-dimensional histogram representing the density of data points in a two-sample plot, wherein inert genes define a main axis of the plot.

FIGS. 5A-5C show examples where an expected ellipsoidal pattern of inert genes does not materialize, due to a signal not being equally represented, which may result in an ellipsoid pattern having a major axis parallel to the concordance line, or angled to and intersecting the concordance line, or curvilinear, where the primary ellipsoidal axis is not a straight line.

FIG. 6 shows a four-parameter logistic response curve, as employed in the present invention.

FIG. 7 shows error bars for a sigmoid that are determined by the error distribution.

FIG. 8 illustrates the ability to identify sub-array (clusters) of probe signal responses that exhibit abnormal behavior, with the aid of a reference array.

FIGS. 9A and 9B show examples of control charting according to the present invention.

FIG. 10 illustrates process steps employed in de-trending, de-warping and the creating of metrics employed to populate profiles used in automatic classification and quality scoring according to the present invention.

FIG. 11 shows x-values, y-values and noise values arranged in a matrix format for processing profiles according to the present invention.

FIG. 12 illustrates the use of a simple model (e.g., Model Zero) to solve for critical profiles used to formulate a computer function relationship to be used for automatic classification and quality scoring.

FIG. 13 illustrates an error matrix (vector) derived from processing the model shown in FIG. 12.

FIG. 14 illustrates a further step in processing for a computer function relationship, in which a first critical profile has been added to the simple model.

FIG. 15 illustrates application of the automatic classification and quality scoring system, using the compute function relationship according to the present invention.

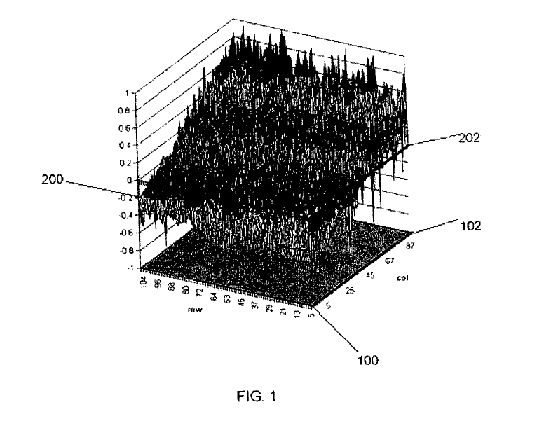

### DETAILED DESCRIPTION OF THE INVENTION

Before the present methods and systems are described, it is to be understood that this invention is not limited to particular method steps, algorithms, software or hardware described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “and”, and “the” include plural referents unless the context clearly dictates otherwise. Thus, for example, reference to “a probe” includes a plurality of such probes and reference to “the channel” includes reference to one or more channels and equivalents thereof known to those skilled in the art, and so forth.

The publications discussed herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed.

### DEFINITIONS

The terms “array”, “microarray” and “bioarray” are used interchangeably herein to refer to a set of spatially separated probed sequences on which biological experiments, such as related to gene expression, can be conducted. An “array”, “microarray” or “bioarray”, unless a contrary intention appears, includes any one-, two- or three-dimensional arrangement of addressable regions bearing a particular chemical moiety or moieties (for example, biopolymers such as polynucleotide sequences) associated with that region. An array is “addressable” in that it has multiple regions of different moieties (for example, different polynucleotide sequences) such that a region (a “feature” or “spot” of the array) at a particular predetermined location (an “address”) on the array will detect a particular target or class of targets (although a feature may incidentally detect non-targets of that feature). Array features are typically, but need not be, separated by intervening spaces. In the case of an array, the “target” will be referenced as a moiety in a mobile phase (typically fluid), to be detected by probes (“target probes”) which are bound to the substrate at the various regions. However, either of the “target” or “target probes” may be the one which is to be evaluated by the other (thus, either one could be an unknown mixture of polynucleotides to be evaluated by binding with the other). An “array layout” refers to one or more characteristics of the features, such as feature positioning on the substrate, one or more feature dimensions, and an indication of a moiety at a given location. “Hybridizing” and “binding”, with respect to polynucleotides, are used interchangeably. A “pulse jet” is a device which can dispense drops in the formation of an array. Pulse jets operate by delivering a pulse of pressure to liquid adjacent an outlet or orifice such that a drop will be dispensed therefrom (for example, by a piezoelectric or thermoelectric element positioned in a same chamber as the orifice).

Any given substrate may carry one, two, four or more arrays disposed on a front surface of the substrate. Depending upon the use, any or all of the arrays may be the same or different from one another and each may contain multiple spots or features. A typical array may contain more than ten, more than one hundred, more than one thousand more than ten thousand features, or even more than one hundred thousand features, in an area of less than 20 cm² or even less than 10 cm². For example, features may have widths (that is, diameter, for a round spot) in the range from about 10 μm to about 1.0 cm. In other embodiments each feature may have a width in the range of about 1.0 μm to about 1.0 mm, usually about 5.0 μm to about 500 μm, and more usually about 10 μm to about 200 μm. Non-round features may have area ranges equivalent to that of circular features with the foregoing width (diameter) ranges. At least some, or all, of the features are of different compositions (for example, when any repeats of each feature composition are excluded the remaining features may account for at least 5%, 10%, or 20% of the total number of features).

Interfeature areas will typically (but not essentially) be present which do not carry any polynucleotide (or other biopolymer or chemical moiety of a type of which the features are composed). Such interfeature areas typically will be present where the arrays are formed by processes involving drop deposition of reagents but may not be present when, for example, photolithographic array fabrication processes are used. It will be appreciated though, that the interfeature areas, when present, could be of various sizes and configurations.

Each array may cover an area of less than 100 cm², or even less than 50 cm², 10 cm² or 1 cm². In many embodiments, the substrate carrying the one or more arrays will be shaped generally as a rectangular solid (although other shapes are possible), having a length of more than 4 mm and less than 1 m, usually more than 4 mm and less than 600 mm, more usually less than 400 mm; a width of more than 4 mm and less than 1 m, usually less than 500 mm and more usually less than 400 mm; and a thickness of more than 0.01 mm and less than 5.0 mm, usually more than 0.1 mm and less than 2 mm and more usually more than 0.2 and less than 1 mm. With arrays that are read by detecting fluorescence, the substrate may be of a material that emits low fluorescence upon illumination with the excitation light. Additionally in this situation, the substrate may be relatively transparent to reduce the absorption of the incident illuminating laser light and subsequent heating if the focused laser beam travels too slowly over a region. For example, a substrate may transmit at least 20%, or 50% (or even at least 70%, 90%, or 95%), of the illuminating light incident on the front as may be measured across the entire integrated spectrum of such illuminating light or alternatively at 532 nm or 633 nm.

Arrays can be fabricated using drop deposition from pulse jets of either polynucleotide precursor units (such as monomers) in the case of in situ fabrication, or the previously obtained polynucleotide. Such methods are described in detail in, for example, the previously cited references including U.S. Pat. No. 6,242,266, U.S. Pat. No. 6,232,072, U.S. Pat. No. 6,180,351, U.S. Pat. No. 6,171,797, U.S. Pat. No. 6,323,043, U.S. patent application Ser. No. 09/302,898 filed Apr. 30, 1999 by Caren et al., and the references cited therein. As already mentioned, these references are incorporated herein by reference. Other drop deposition methods can be used for fabrication, as previously described herein. Also, instead of drop deposition methods, photolithographic array fabrication methods may be used. Interfeature areas need not be present particularly when the arrays are made by photolithographic methods.

Following receipt by a user of an array from a manufacturer, it will typically be exposed to a sample (for example, a fluorescently labeled polynucleotide or protein containing sample) and the array then read. Reading of the array may be accomplished by illuminating the array and reading the location and intensity of resulting fluorescence at multiple regions on each feature of the array,. For example, a scanner may be used for this purpose which is similar to the AGILENT MICROARRAY SCANNER manufactured by Agilent Technologies, Palo Alto, Calif. Other suitable apparatus and methods are described in U.S. Pat. Nos. 6,406,849, 6,371,370, and U.S. patent application Ser. No. 10/087447 “Reading Dry Chemical Arrays Through The Substrate” by Corson et al., and Ser. No. 09/846125 “Reading Multi-Featured Arrays” by Dorsel et al.. However, arrays may be read by any other method or apparatus than the foregoing, with other reading methods including other optical techniques (for example, detecting chemiluminescent or electroluminescent labels) or electrical techniques (where each feature is provided with an electrode to detect hybridization at that feature in a manner disclosed in U.S. Pat. No. 6,251,685, U.S. Pat. No. 6,221,583 and elsewhere). A result obtained from the reading may be used in that form or may be further processed to generate a result such as that obtained by forming conclusions based on the pattern read from the array (such as whether or not a particular target sequence may have been present in the sample, or whether or not a pattern indicates a particular condition of an organism from which the sample came). A result of the reading (whether further processed or not) may be forwarded (such as by communication) to a remote location if desired, and received there for further use (such as further processing).

A “biopolymer” is a polymer of one or more types of repeating units. Biopolymers are typically found in biological systems and particularly include polysaccharides (such as carbohydrates), and peptides (which term is used to include polypeptides and proteins) and polynucleotides as well as their analogs such as those compounds composed of or containing amino acid analogs or non-amino acid groups, or nucleotide analogs or non-nucleotide groups. This includes polynucleotides in which the conventional backbone has been replaced with a non-naturally occurring or synthetic backbone, and nucleic acids (or synthetic or naturally occurring analogs) in which one or more of the conventional bases has been replaced with a group (natural or synthetic) capable of participating in Watson-Crick type hydrogen bonding interactions. Polynucleotides include single or multiple stranded configurations, where one or more of the strands may or may not be completely aligned with another.

“nucleotide” refers to a sub-unit of a nucleic acid and has a phosphate group, a five-carbon sugar and a nitrogen containing base, as well as functional analogs (whether synthetic or naturally occurring) of such sub-units which in the polymer form (as a polynucleotide) can hybridize with naturally occurring polynucleotides in a sequence specific manner analogous to that of two naturally occurring polynucleotides.. For example, a “biopolymer” includes DNA (including cDNA), RNA, oligonucleotides, and PNA and other polynucleotides as described in U.S. Pat. No. 5,948,902 and references cited therein (all of which are incorporated herein by reference), regardless of the source. An “oligonucleotide” generally refers to a nucleotide multimer of about 10 to 100 nucleotides in length, while a “polynucleotide” includes a nucleotide multimer having any number of nucleotides. A “biomonomer” references a single unit, which can be linked with the same or other biomonomers to form a biopolymer (for example, a single amino acid or nucleotide with two linking groups one or both of which may have removable protecting groups).

When one item is indicated as being “remote” from another, this is referenced that the two items are at least in different buildings, and may be at least one mile, ten miles, or at least one hundred miles apart.

“May” means optionally.

Methods recited herein may be carried out in any order of the recited events which is logically possible, as well as the recited order of events.

The term “accuracy”, as used herein, refers to the measure of exactness of an analytical method, or the closeness of agreement between the value which is accepted either as a conventional, true value or an accepted reference value, and the value found.

“Analytical sensitivity”, as used herein, refers to the lowest reading/concentration that can be distinguished from background noise.

“Array patterns” are geometrical patterns over the face of an array produced by non-uniform conditions during array manufacture and/or hybridization.

“Build bias” typically comes from a combination of factors, e.g., sample preparation, amplification, and the purification process involved in batch “printing” of arrays. Storage and contamination problems can further complicate such error sources.

“Channel bias” arises from noise factors impacting each channel (or array) due to biological preparation, labeling, and/or general hybridization conditions.

The “dynamic range” of an array refers to the interval between the upper and lower RNA concentration values in the sample (including these concentrations) for which it has been demonstrated that the array has a suitable level of precision and accuracy.

“Gradient effects” are those in which there is a pattern of expression signal intensity which corresponds with specific physical locations within the chip and which are characterized by a gradual slope in the expression values from one end of the chip to another. This can be caused by variations in chip design, manufacturing, and/or hybridization procedures, for example.

The “limit of detection” (LOD) is defined as the lowest concentration of an analyte in a sample that can be detected, not quantitated.

The “limit of quantitation” (LOQ) is defined as the lowest concentration of an analyte in a sample that can be determined with acceptable precision and accuracy under the stated operational conditions of the method.

The “linear dynamic range” of an analytical procedure is the interval between the upper and lower concentration values (amounts) of analyte in the sample (including these concentrations) for which it has been demonstrated that the analytical procedure has a suitable level of precision, accuracy and linearity.

The term “linearity” refers to the degree to which a method elicits test results that are directly proportional to those values/concentrations that are being tested, after any baseline offset.

Statistical definitions which follow are generally referenced to any statistical text book and robust statistical definitions which follow are referenced to Robust Statistics, by Peter J. Huber, 1981, John Wiley & Sons, New York.

“Measures of central tendency” include any measure indicating a center of the distribution of a set of data. A finite set of data may be either a population or a sample (in other words, either a complete set of data or a sample from some larger, but unknown, set of data). In either case, these measures can provide useful information regarding the characteristics of the data. The mode, the median, and the arithmetic mean are common indices of central tendency. For specific distributions, such as the normal distribution, the three measures have the same value, but more often than not, the three measures have different values. It can be useful to report all three measures, as each represents something slightly different. By far the most commonly used and most useful measure of central tendency is the (arithmetic) mean. The geometric mean and harmonic mean, although less commonly applied in statistics than those mentioned above, are very useful for some special types of data sets.

The mean of a finite set of n numerical observations is obtained by adding the observations and dividing the total by the number of observations. The mean of the numbers X₁, X₂, . . . , Xₙ is

$$\frac{{\sum }_{i = 1}^{n} {X}_{i}}{n} = \frac{{X}_{1} + {X}_{2} + … + {X}_{n}}{n} \qquad ( 1 )$$

Note that the arithmetic mean can be deemed as the value, designated as \overline{x} (x-bar), for which the absolute value of the sum of the squared differences from the mean

$${\sum }_{i = 1}^{n} {( {X}_{j} - \overline{x} )}^{2}$$

is as small as possible (minimum=zero). The term “average” is often used to indicate arithmetic mean, but it is also used more generally to refer to any of the measures of central tendency.

The mean of a sample and the mean of a population are sometimes distinguished by notation. For example, \overline{x} (“x-bar”) is often used to denote the sample mean and μ (Greek letter mu) or \overline{X} (“X-bar”) the population mean. The mean of a continuous distribution with distribution function f(x) is obtained by the integral:

$${\int }_{- ∞}^{∞} x f ( x ) ⅆ x \qquad ( 2 )$$

The means of several sets of data may be combined into an overall mean without the need to refer back to the raw data. If \overline{x}₁, \overline{x}₂, . . . , \overline{x}ₖ are the means corresponding to sets of data of size n₁, n₂, . . . , nₖ, then the mean of the combined data set is the weighted mean:

$$\frac{{\sum }_{i = 1}^{k} {n}_{i} {\overline{x}}_{i}}{{\sum }_{i = 1}^{k} {n}_{i}} = \frac{{n}_{1} {\overline{x}}_{1} + {n}_{2} {x}_{2} + … + {\overline{n}}_{k} {\overline{x}}_{k}}{{n}_{1} + {n}_{2} + … + {n}_{k}} \qquad ( 3 )$$

A mode of a finite set of numerical observations is an observation that occurs most frequently. A set of observations can have more than one mode.

The median of a finite set of numerical observations is that value for which half of the numbers are larger and half are smaller. Thus, the median position of an ordered list of data is given by index (n+1)/2, where n is the total number of observations. In the case of an odd number n, the median is the middle number. In the case of an even number n, the median is usually taken as the arithmetic mean of the two middle observations.

For a set x₁, x₂, . . . , xₙ of non-negative numbers, the geometric mean is the n^{th} root of the product, i.e.,

$$\sqrt[n]{{x}_{1} {x}_{2} … {x}_{n}} \qquad ( 4 )$$

The geometric mean may be useful with data for which the ration of any two consecutive numbers is nearly constant, such as is often the case with the ratio of probe signal intensities. The geometric mean is always less than or equal to the arithmetic mean.

“Measures of dispersion” or “measures of variability” include any measure indicating the amount of scatter about a central point. A finite set of data may be either a population or a sample (e.g., either a complete set of data or a sample from some larger, but unknown, set of data). In either case, measures of dispersion or variability may provide useful information regarding the characteristics of the data. In particular, in order to evaluate the validity of a generalization made from a sample, something must be known about the variability of the population from which the sample is obtained.

The most commonly used measures of dispersion are the variance and the standard deviation. However, other measures of dispersion, such as range, mean deviation, means absolute deviation, standard units, coefficient of variation and fold change, for example, are available and may provide additional information about the data.

The range of a set of numbers is simply the difference between the largest number and the smallest number.

The mean deviation or average deviation of a set of numerical observations is the sum of the distances of the observations from their mean:

$$mean deviation = \frac{{\sum }_{j = i}^{n} \vert {x}_{j} - x \vert}{n} \qquad ( 5 )$$

where x-bar has been previously defined.

Note that the distances are measured by the absolute value of the difference between the particular x value and the mean, in each case. Note further that mean deviation is minimized by replacing x-bar with the median value of the sample x₁, x₂, . . . , xₙ.

When a scale is a nuisance parameter, it often makes sense to estimate it as robustly as possible. The simplest robust scale estimator is the median absolute deviation (MAD). The MAD has a breakdown point of ½ and a relatively poor efficiency of 37%. MAD is defined as:

MAD=median|xᵢ−median(xᵢ)| (6)

The variance (commonly denoted by σ²)of a population of size n is defined as the average of the squares of the differences from the mean μ:

$${σ}^{2} = \frac{{\sum }_{j = 1}^{n} {( {x}_{j} - μ )}^{2}}{n} \qquad ( 7 )$$

The standard deviation (σ) or root-mean-square deviation is the square root of the variance.

The variance of a sample size n and mean \overline{x} is defined to be:

$${s}^{2} = \frac{{\sum }_{j = 1}^{n} {( {x}_{j} - \overline{x} )}^{2}}{n - 1} \qquad ( 8 )$$

This statistic is sometimes also called the sample estimate of population value of the variance, or sample variance. The standard deviation (s) of a sample size n and mean \overline{x} is the square root of the sample variance. This statistic may also be called the sample estimate of population value of the standard deviation, or sample standard deviation.

Standard deviations may be useful for comparing numbers belonging to different sets of data when they are expressed as standard units. Standard units, also known as standard scores, or z-scores, tell how many standard deviations an item is above or below the mean of the set of data to which it belongs. Standard units are defined as:

$$\begin{matrix}z = \frac{x - \overline{x}}{s} for a sample , \\ or & ( 9 ) \\ z = \frac{x - μ}{σ} for a population . & ( 10 )\end{matrix}$$

A measure of dispersion that has no theoretical value, but is sometimes uses as a quality criterion is the coefficient of variation, which is the standard of deviation expressed as a percentage of the arithmetic mean. The coefficient of variation is thus defined as:

$$CV = \frac{s}{\overline{x}} \cdot 100 \% \qquad ( 11 )$$

The coefficient of variation gives the maple standard deviation as a percentage of the sample mean. It is a measure of relative variation which expresses the magnitude of the variation relative to the magnitude of the data.

The fold change is a ratio of the average probe signal intensities between a test and control array:

$$FoldChange = \frac{AverageSignalTestProbe}{AverageSignalControlProbe} \qquad ( 12 )$$

Consequently, ln(FoldChange)=ln(AverageSignalTestProbe)−ln(AverageSignalControlProbe). The mean, standard deviation and coefficient of variation of fold change may be determined through examination of the natural logarithms of the differences in prove signals and converting back to the original scale. Similarly, the detectable fold change may be calculated through examination of the two-sided statistical tolerance interval for the natural logarithmic difference in background values (local background values, negative controls or zero positive controls) and converting back to the original scale through exponentiation.

“Measures of association” include the correlation coefficient and sample concordance coefficient. Statistical procedures often involve the measurement of two variables (e.g., the measurement and comparison of probe signal intensities on two bioarrays). A common question that arises during such procedures is as to the manner in which scores on the first variable are related to scores on the second variable. The coefficient of correlation (or Pearson product-moment coefficient of correlation) assigns precise numerical values to these relationships. For example, for random variable X and Y, the correlation coefficient ρ is defined as:

$$ρ ( X , Y ) = \frac{{\sum }_{j = 1}^{n} ( {x}_{j} - \overline{x} ) ( {y}_{j} - \overline{y} )}{\sqrt{{\sum }_{j = 1}^{n} {( {x}_{j} - \overline{x} )}^{2}} \sqrt{{\sum }_{j = 1}^{n} {( {y}_{j} - \overline{y} )}^{2}}} \qquad ( 13 )$$

The coefficient ρ=ρ(X,Y) satisfies −1≦ρ≦1. The value ρ=0 indicates no linear correlation, whereas ρ>0 indicates positive correlation and p <0 indicates negative correlation. This statistic is most widely used to measure the strength of the linear relationship between two variables. When two random variables are independent, ρ=0. If two random variables are perfectly linearly related (e.g., Y=a +bX, where a and b are constants), then the coefficient of correlation reaches one of the extreme values of +1 or −1. In either case, X and Y are then referred to as perfectly correlated.

The concordance correlation is a useful reproducibility index that may be used to represent the correlation in signal response between a test microarray relative to a control microarray, for example. For a two sample plot of test versus control microarray signal values, points that fall on the forty-five degree line (line passing through the origin and forming a forty-five degree angle with the X-axis as well as the Y-axis, i.e., the concordance line) are said to be concordant.

Consider pairs of signal values (yᵢ₁,yᵢ₂), wherein i=1,2, . . . , n, which are independently selected from a bivariate population with sample means

$${\overline{y}}_{j} = \frac{1}{n} {\sum }_{i = 1}^{n} {y}_{ij} ,$$

where j=1, 2, . . . , n. The sample covariance is defined as:

$$COV ( y1 , y2 ) = ( \begin{matrix}{s}_{1}^{2} & {s}_{12} \\ {s}_{21} & {s}_{2}^{2}\end{matrix} ) \qquad ( 14 )$$

where

$$\begin{matrix}{s}_{j}^{2} = \frac{1}{n} {\sum }_{i = 1}^{n} {( {y}_{ij} - {\overline{y}}_{j} )}^{2} , j = 1 , 2 \\ and {s}_{12}^{2} = \frac{1}{n} {\sum }_{i = 1}^{n} ( {y}_{i1} - {\overline{y}}_{1} ) ( {y}_{i2} - {\overline{y}}_{2} ) .\end{matrix}$$

The sample concordance correlation coefficient may be calculated as:

$${ρ}_{c} = \frac{2 {s}_{12}}{{s}_{1}^{2} + {s}_{2}^{2} + {( {\overline{y}}_{1} - {\overline{y}}_{2} )}^{2}} \qquad ( 15 )$$

The sample concordance coefficient may also be calculated as \hat{ρ}_{c}=\hat{ρ}Ĉ_{b}, where \hat{ρ} is the sample Pearson correlation coefficient, and the sample bias correction factor

$${\hat{C}}_{b} = {[ ( \hat{v} + \frac{1}{\hat{v}} + {\hat{u}}^{2} ) / 2 \}}^{- 1} \qquad ( 16 )$$

with sample location and scale shifts

$$\hat{u} = ( {\overline{y}}_{1} - {\overline{y}}_{2} ) / \sqrt{{s}_{1} {s}_{2}} \qquad ( 17 )$$

and

\hat{v}=s₁/s₂ (18)

respectively.

Asymmetry is calculated as:

$$Asymmetry = \frac{\vert {\sum }_{i = 1}^{N} {max ( {y}_{i} - {x}_{i} , 0 )}^{2} - {\sum }_{i = 1}^{N} {max ( {x}_{i} - {y}_{i} , 0 )}^{2} \vert}{N} \qquad ( 19 )$$

“Confidence intervals for the mean” cover the population mean with a stated confidence level, that is, for a certain proportion of the time. A two-sided 100(1−α)% confidence interval for the mean μ of a normal distribution is given by:

\overline{x}±t_{(1-α)/2:n-1)}•s/\sqrt{n} (20)

One-sided 100(1−α)% confidence intervals are obtained by replacing α/2 with α(and ± with either + or −) in equation (21).

Confidence intervals for the mean, standard deviation, coefficient of variation, correlation coefficient and concordance correlation coefficient can all be calculated according to know formulae, which were also included in the appendix of application Ser. No. 60/375,251, incorporated herein by reference in its entirety.

The term “precision”, as used herein, refers to a measure of the degree of repeatability of an analytical method under normal operations.

The term “trending” is used to denote offset of a signal pattern across microarray probed included with gene expression signals.

The term “de-trending” refers to processing probe signals to remove trending patterns from the probe signals of a microarray.

The term “warping” is used to refer to a result where, when comparing results from two or more channels a user sees patterns produced by the ubiquitous population of “constant” (“inert”) genes that are non-ideal in shape and form. The pattern deviates from the symmetric, ellipsoidal pattern that is expected when signals representing inert genes are accurately represented.

The term “de-warping” refers to processing performed to remove warping patters for all feasible comparisons.

The present invention applies de-trending algorithms to simultaneously estimate and remove non-biological distortions from inputted array data, thereby significantly improving the biological content of the data. Blocking and gradient effects due to errors introduced by chip manufacturing and the printing process may be addressed, as well as artifacts introduced by errors or inconsistencies in preparing the biological samples on the array. The probed should be arranged randomly to provide better statistical results. Low frequency anomalies overlaying the probe signals may be removed, as well as higher frequency anomalies caused by production shift factors imposed on the array.

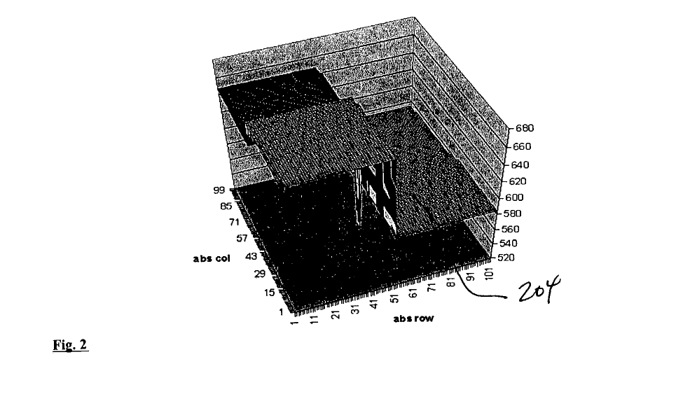

A blocking effect includes a sudden discontinuity among probe subsets in the array, such as shown at 204 in FIG. 2, for example. Such discontinuities contain high frequency components that may become mixed with the high frequency biological information of the relevant probe signals. Therefore it is important to identify the exact probe subsets where the blocking effects occur on the array so that they can be effectively filtered out. The manufacturer of the array being used will often be aware of the blocking effects for that particular array and will supply information to identify the exact locations of the occurrences of blocking on the microarray chip. From this information, an analysis program may be designed to precisely filter out the blocking effects. A blocking factor (i.e., dummy variable) may be derived from the manufacturer's information and inputted to support a shift vector for probes that are printed with the pen or combination of pens causing the blocking effects. Otherwise, gradient analysis and filtering are applied in an effort to remove blocking effects as well as gradient effects.

A typical approach is to enter such blocking factors and use these blocking factors with a statistical technique call response-surface methodology that uses a second order surface to approximate the global gradient effects. Additionally, there may be localized “hot” or “cold” spots (i.e., regional effects) that deviate from the global gradient effects. The most generalized application removes blocking effects, global gradient effects, and regional gradient effects.

The present invention further provides means for performing automated quality management, wherein determinations may be automatically performed to classify the information received from a microarray as “good/pass” (e.g., sufficiently reliable) or “bad/fail” (e.g., not recommended to be used to rely upon the values obtained there from). A third category of microarrays would typically be marked for further inspection/analysis, such as by human inspection. Not only is a quality assessment of microarrays able to be automatically performed, but data improvement may also be accomplished through the use of the de-trending with de-blocking and de-warping techniques described herein.

The present invention applies de-trending algorithms to simultaneously estimate and remove non-biological distortions from inputted array data, thereby significantly improving the ratio of biological content of the data to noise. In general, de-trending removes (filters) all low-frequency and block patterns that are inherently added to the gene expression patterns of the array probe signals. If probes are randomly placed on the array by design, then de-trending removes all low-frequency and blocking patterns from the probe signals. Such filtering may be accomplished, for example, by a harmonic model plus shift effects for the blocking patterns. However, a second order polynomial model plus shift factors, plus statistical predictor methods using similarity transforms, such as SLS™ (see U.S. Pat. No. 6,188,969) or that described in co-pending, commonly owned Application (serial no. not yet assigned, Attorney's Docket No. 10030281-2) filed Mar. 27, 2003 and titled “Method and System for Predicting Multi-Variable Outcomes”; and U.S. Provisional Application No. 60/368,586, filed Mar. 29, 2002; each of which is incorporated herein, in its entirety, by reference thereto) regional terms may be adequate in practice. Further, the SLS™ regional terms are typically not even necessary to achieve satisfactory results. The de-trending model may be optimized by least-squares regression for each array and then subtracted from the probe signals.

Examples of artifacts produced by influences other than the biological materials being studied (“non-biological distortions”) can generally be grouped into three primary categories: array patterns, channel bias and build/batch bias. Array patterns are geometrical patterns over the face of an array produced by non-uniform conditions during array manufacture and/or hybridization. Channel bias arises from noise factors impacting each channel (or array) due to biological preparation, labeling, and/or general hybridization conditions. Build/batch bias typically comes from a combination of factors. For example, factors such as sample/reagent preparation, amplification, and the purification process involved in batch “printing” of arrays may contribute to build bias. Storage and contamination problems can further complicate such error sources.

The array manufacturing process tends to cross boundaries created by discreteness in the manufacturing structure. Such discreteness tends to produce shifts in the properties of the printed probes. For example, some producers of array probes may create higher-performance probes than other producers. Temporal effects may also contribute a trend in probe properties. For example, uneven or unequal evaporation of plate wells may cause a trend to occur in for cDNA based arrays during printing.

Patterns in hybridization conditions can overlay another trend on top of manufacturing patterns. For example, selected probes may be inferior due to degradation factors such as a depurination factor specific to nucleotide “A” in the probe sequence content. If the array design is balanced and random (i.e., no biological-based patterns on the chip), then removal of non-biological shifts and trends may be accomplished by a generalization of conventional statistical response-surface regression as documented at government web sites: http:www.itl.nist.gov/div898/handbook/pri/section3/pri336.htm and http://www.itl.nist.gov/div898/handbook/pri/section4/pri473.htm, for example, such models can be based on probe coordinates with boundary and block effects added. This will remove trends and shifts. If a biologically-based pattern is designed onto the array, then the regression model must also include this known pattern into the analysis. For example, some microarray manufacturers group high abundance genes in a region of the array separate from low abundance genes. Also, an array may contain blocks of probes with the same or similar sequence so that target depletion effects occur. In this case, a probe density variable is included Still further, a correction effect may be added to account for variations in probe performance due to its sequence and/or sequence content (as in the example given above regarding depurination of nucleotide “A”).

De-Blocking

De-blocking processing is performed to eliminate signal shift factors for specific, mutually exclusive subsets within the complete array probe set. These signal shift factors are referred to as “blocking effects”. Blocking effects are produced during the array processing. One common cause of blocking effects is the presence of distinct configurations in the printing devices or producers for each probe. These shift factors are included in the de-trending model.

De-Warping

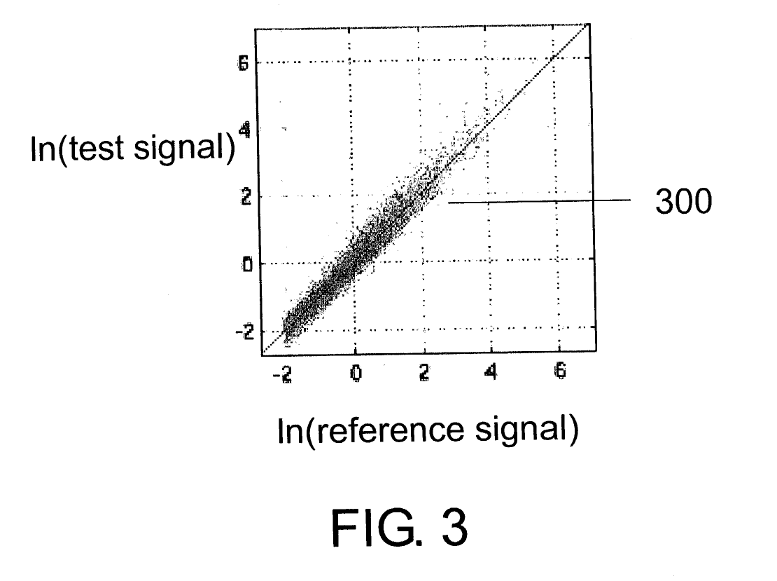

Although de-trending normalizes the total signal generated upon analysis of microarray data, it does not address or compensate for disparities inherent in the use of more than one signal channel (channel (array) non-equivalence). Hence, when comparing results from two or more channels (e.g., two colors on one array or single colors from two or more different arrays), a user is likely to see patterns produced by the ubiquitous population of “constant” (“inert”) genes that are non-ideal in shape and form. “Constant” or “inert” genes refer to genes which are substantially inert for a specific study. Hence, these genes tend to have “constant” expression levels in the study. The population properties of such genes are constant for all experiments in the study and are therefore useful for normalization purposes. In such a situation, when the signal values (or ln(signal)) of these genes (or ln(signal)) are plotted against one another, with values from a first of two channels plotted along the x-axis and values form a second of the two channels plotted along the y-axis, the resultant plot should appear ellipsoidal, with the major axis of the ellipse running along an imaginary line 302 passing through the intersection of the x and y axis (origin) at a forty-five degree angle to each of the axes (the “concordance line”), as shown by plot 300 in FIG. 3. Note that although the example shown and described here is for two channel comparison, that the present invention is not limited to analysis of only one or two channels, but may similarly and simultaneously analyze and compare three or more channels, as the systems and processes herein are capable of high dimensional functioning. It should be noted that this is the performance and resulting plot that de-warping processing, according to the present invention, aims to achieve.

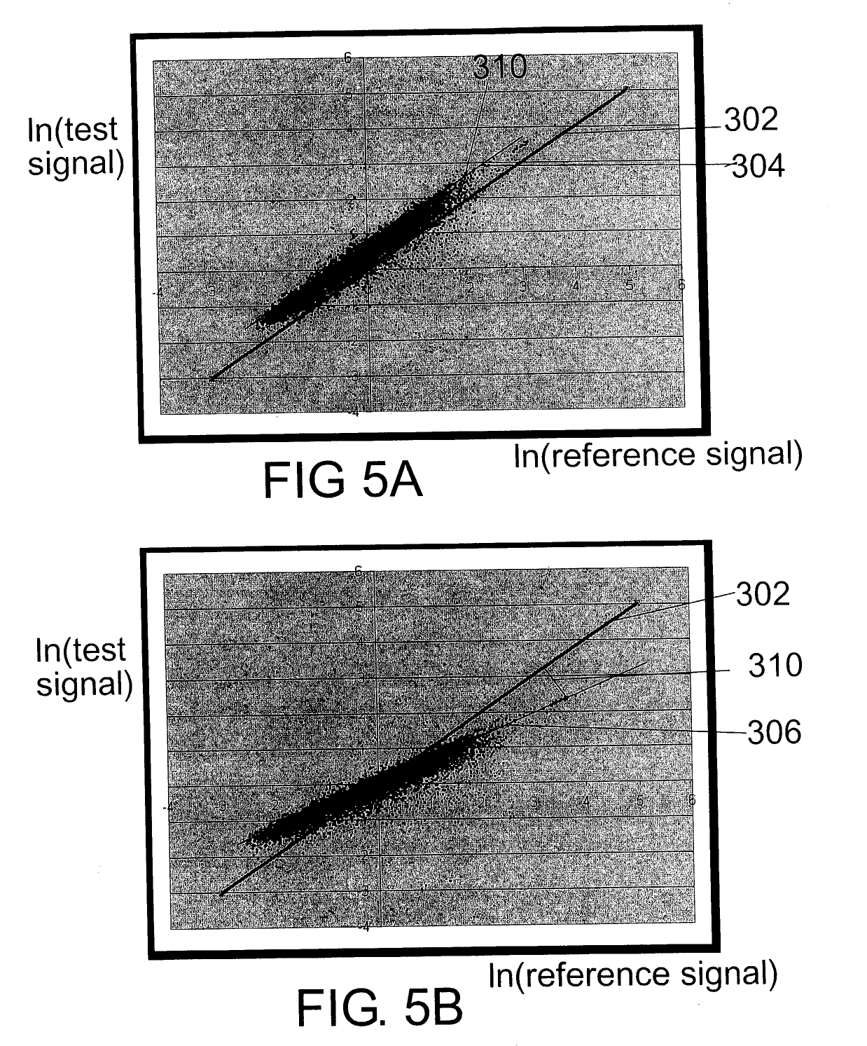

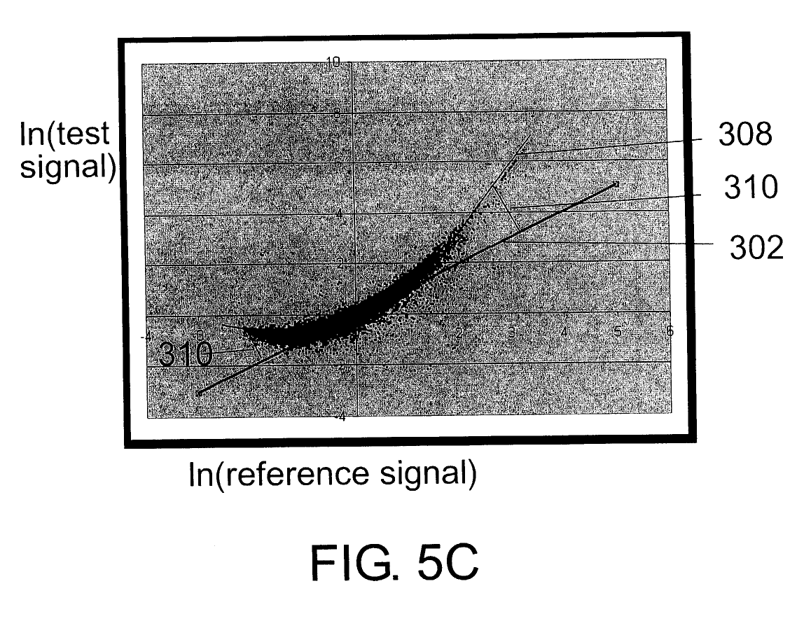

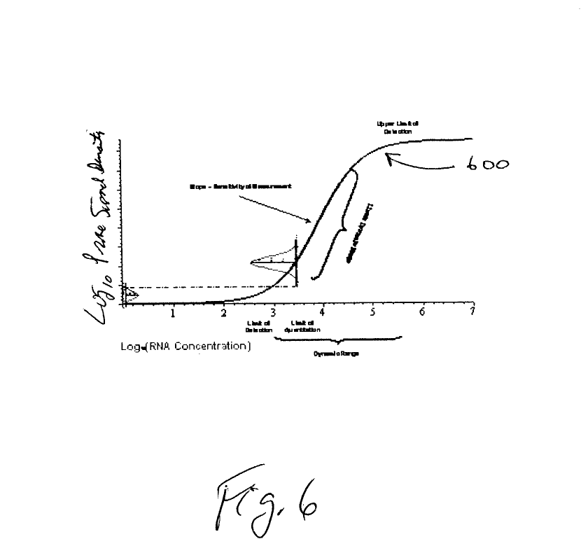

In many cases, the “constant” or “inert” population of genes may be problematic for one or more reasons. For example, rather than the expected ellipsoidal pattern of inert genes shown in FIG. 3, the signal may not be equally represented, resulting in an ellipsoid pattern having a major axis 304 parallel to the line 302, as shown in FIG. 5A, , or angled 306 to and intersecting line 302 (if extended) as shown in FIG. 5B, or curvilinear 308 as shown in FIG. 5C, where the primary ellipsoidal axis 308 is not a straight line. These distortions may be partially induced by improper thresholds set by the manufacturer of the rnicroarray chip for low and high array signals.

The present invention utilizes a universal method of channel normalization for both single and dual channel array platforms called de-warping. De-warping may also be applied to many channels simultaneously, as noted above. This normalization procedure has been validated on many thousands of oligo and cDNA based arrays across a rich variety of applications and experimental conditions. The results have passed critical evaluations by expert biologists in industry, academia, and government.

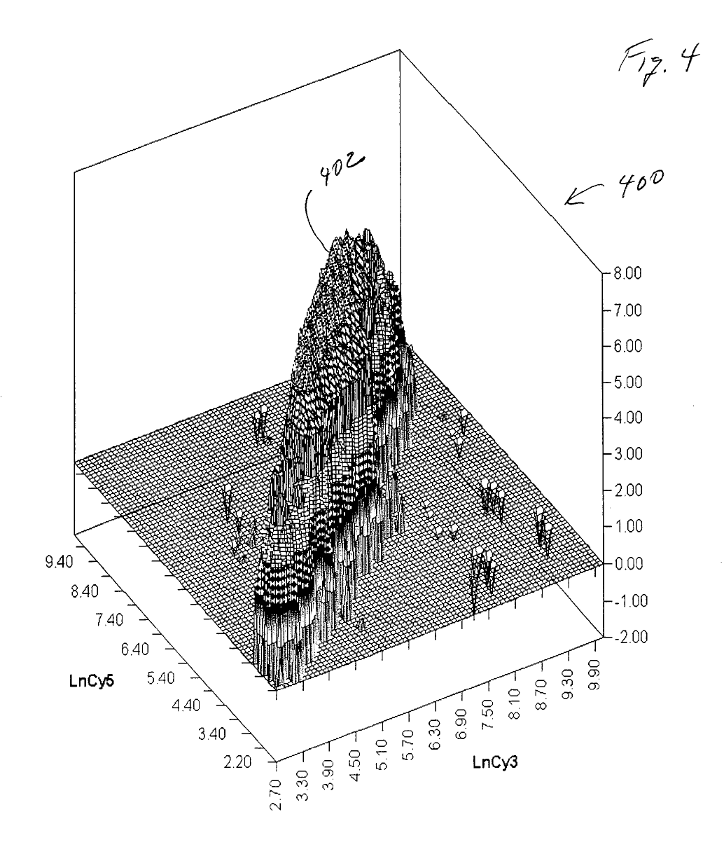

In essence de-warping corrects the pattern created by “constant” genes in the plot of the two or more channels of log signal (In signal of scanner RLU signals) on a two-sample (or more than two sample) plot. Initially one then forms a two-dimensional histogram (or multi-dimensional histogram, i.e., greater than two-dimensional) by binning (i.e., data partitioning to form frequency (count) plots, i.e., histograms) both axes to form grid squares and plotting frequency-of-occurrence within these squares on a third axis (or additional axis). The resulting histogram 400 represents the density of points in the two-sample plot (in the example shown), and the frequency density resembles a mountain range, see FIG. 4. The major mode of this histogram is an elongated ridge 402 formed by the population of inert genes ranging over their typical variations in abundance. This ridge 402 provides a useful definition of an expression baseline, since such inert genes are neutral, or inert, to the biological perturbations of the study experiments. The ridge is then mathematically transformed into a linear straight line according to the relative error properties of the signal channels. If the channels all have similar sized errors, then the orthogonal deviation from this ridge locus to the diagonal is subtracted for each probe, so that the ridge locus is effectively corrected to the nearest point on the diagonal for each probe, as indicated by arrows 310 in each of FIGS. 5A-5C, and hence, rotated to the desired forty-five degree diagonal position. If select channels are designated as essentially error-free, i.e., reference channels, then the deviation from this ridge locus to the diagonal but orthogonal to such reference channels is subtracted for each probe, so that the ridge locus is effectively corrected to the diagonal for each probe leaving reference values unchanged, as indicated by arrows 310 in each of FIGS. 5A-5C, and hence rotated to the desired forty-five degree diagonal position. In summary the de-warp correction is only in the direction of significant error. The final corrected (“de-warped”) two-sample plot has the expected pattern for the population of “inert” genes from two ideally equivalent channels.

Analytical Performance Metrics

According to one aspect of the invention, an assessment of the analytical performance and quality of each bioarray may be automatically performed. Various high-value analytical performance metrics may be measured, calculated and reported for each bioarray, thereby allowing a user to quantify the inherent quality of each hybridized array. These quality control metrics may be generated both before and after de-trending and de-warping, which enables the user to quantify improvements in array data. Analytical performance scanning metrics may be generally grouped into the following categories: accuracy; precision; analytical sensitivity; linearity; and dynamic and linear dynamic range. Some important concepts for validation of analytical procedures can be found in “Validation of Analytical Procedures: Methodology”, by the European Agency for the Evaluation of Medicinal Products, Human Medicines Evaluation Unit, Step 4, Consensus Guideline, Nov. 6, 1996, which is incorporated herein, in its entirety, by reference thereto (see also: http://www.mcclurenet.com/EMEA_PDFs/Q2a.pdf).

Accuracy

In the context of microarray analysis, accuracy pertains to the degree of bias between the (unknown) true signal and the observed signal reported. For quality control purposes, the present invention utilizes an internal reference array as an acceptable reference, particularly for one-color platforms. A reference array is simply an ideal common reference for correction of all arrays. For any specific comparison between two corrected signal channels, the common reference will cancel out, like a common ground for electric circuits. If the ideal reference is designed as the best representative of a set of arrays, i.e., the average of the set, then one can use individual array-reference comparisons for quality-control evaluations. The internal reference array may be generated through examination of the signal responses of inert genes across hundreds of arrays generated under tightly controlled experimental conditions. Assessments of accuracy of new experimental results may then be performed relative to this reference. A gene-by-gene comparison is performed, where one channel is the reference and the other channel is the experiment. One axis of the plot comparison has the expression levels of the genes in the experiment plotted against it, while a second axis has the expression levels of the reference genes plotted against it, resulting in the elliptical population plot described above. The middle of the population (i.e., along the concordance line) is created by the inert genes.

The present invention utilizes a reproducibility index, such as a concordance correlation coefficient to evaluate the error properties of an array. For example, given a two-sample plot of the paired signal responses from an experimental array versus the reference array, perfect concordance represents the correlation between array readings that fall on the 45° line through the origin (i.e., the concordance line), as described above. Concordance provides a measure of an assay's accuracy, precision, location and scale shift relative to the internal reference. Departures from the reference can be measured by how far the signal pairs deviate from the concordance line in the scale of 1 (perfect agreement) to 0 (no agreement) to −1 (perfect reversed agreement). The appearance of the population, as plotted, for the extreme concordance values of 1, 0 and −1 are: a perfect alignment of all points on the forty-five degree (diagonal) concordance line for a concordance value of 1; a circle of points having no directionality (i.e., no ellipse with a major axis) for a concordance value of 0; and a perfect alignment of all point on a minus forty-five degree line for a concordance value of −1. Departures from the reference values may be caused by precision and/or accuracy factors, which may be correctable by calibration.

Accuracy is a bias correction factor that measures how far the best-fit line deviates from the 45° line. No deviation occurs when concordance is 1. The further concordance is from 1, the greater the deviation from the 45° line. The present invention corrects for systematic process bias (when the average of the ellipsoid is off the 45 degree diagonal line) through de-trending. Concordance tends to be greater than 98% for acceptable arrays. Probes of inert genes should produce points along the diagonal according to abundance, as a measure of accuracy. Off diagonal fluctuations of such points reflect precision. Hence, the off-diagonal width of such a pattern centered perfectly on the diagonal measures precision. If the pattern is not centered on the diagonal, then concordance includes both precision and accuracy errors.

constant differences in mean signal response between the experimental array and the reference array result in location shifts. Location shifts often occur due to systematic process biases and result in the best-fit line being parallel to the 45° line when the pattern has a 45° angle. No deviation occurs when location shift is 1. The further location shift is from 1, the greater the deviation from the 45° line. Location shift is a ratio of the averages of the two signals. So when the ratio is not 1, the expression values being plotted are off diagonal. The present invention corrects for systematic process bias through de-trending. The logs (e.g., natural log, denoted as “ln”) of the location shifts tend to be near zero for acceptable arrays. Location shift is also measured by the average of total ln(signal) of each channel.

Differences in mean signal responses that vary as a function of signal intensity result in scale shifts. Scale shifts result in the best-fit line being at an angle crossing the 45° line, as shown in FIG. 5B, for example. No deviation occurs when scale shift is 1. The further scale shift is from 1, the greater the deviation from the 45° line. Scale shift if measured by looking at the locus of the ridge of the ellipsoid plotted. A “bin window” is employed, which breaks the diagonal into segments that are then compared with one another. By observing the ratios (between experimental values and reference values) in the identified windows, localized averages are developed. An attempt is then made to trace the diagonal, using the calculated local averages. If there is a scale shift, the ratio is a function of abundance. For example, the scale shift ration may be high in one window or group of windows, have a value of one in another window or group of windows (e.g., at the central portion of the diagonal) and have a low ratio in another window or group of windows (e.g., portion of diagonal line on the opposite end of the central portion). The present invention corrects for scale shifts through de-warping, as described previously. Scale tends to be greater than 0.85 for acceptable arrays.

The present invention generates robust estimates of location and scale, using so-called “M-estimators”, for example. M-estimators minimize objective functions more general that the familiar sum of squared residuals associated with the sample mean. For simultaneous M-estimation of location and scale, the log-likelihood equations are generalized, incorporating a tuning constant c₁ to give:

$${\sum }_{i = 1}^{n} ψ ( \frac{{x}_{1} - {T}_{n}}{c \cdot {s}_{n}} ) = 0 \qquad ( 21 )$$

where

n=number of data elements (i.e., size of the data);

ψ=M-estimation function;

x=datum point;

s=estimate of scale; and

T=estimate of location.

Precision

Precision can be decomposed into different components. Repeatability, as measured by the present invention, pertains to array results generated under the same experimental conditions (i.e., inter-assay precision). Intermediate precision pertains to results within lab variations due to random events such as different days on which the experiments were performed, different analysts, different equipment used, and the like. Reproducibility refers to the results of collaborative studies between laboratories. The present invention generates a variety of different types of estimates of precision, including: standard deviation of signal response; coefficient of variation of signal response; comparative precision; concordance correlation; and minimum detectable fold change.

Standard Deviation of Signal Response

The standard deviation of (natural logarithm) signal response is a measure of the spread in signal responses for an array. Standard deviations are useful for comparing signal responses across different sets of arrays when expressed in standard units. Standard units, also known as standard scores, or z-scores, tell the user how many standard deviations an item is above or below the mean of the set of data to which it belongs. The standard deviation of signal response on the natural logarithm scale can be mathematically shown to be an excellent approximation to the coefficient of variation of signal response on the original scale for array data. Two-sided confidence limits are provided [Default: 95% two-sided confidence interval. The present invention provides classical as well as robust estimation of standard deviations.

Coefficient of Variation of Signal Response

The coefficient of variation of signal response is simply the standard deviation of In (natural logarithm) signal response, which can be expressed as a percentage if desired. The coefficient of variation is a measure of the variation in signal response relative to its average. Two-sided confidence limits are provided [Default: 95% two-sided confidence interval]. The present invention provides various methods of robust estimation.

Comparative Precision

Comparative precision may be calculated using the Pearson product-moment coefficient of correlation of experimental array signals versus the internal reference signals. Comparative precision measures how far each pair of signals deviated from the best-fit line of the pairs of signals from the experimental array versus the reference array. A precision value of 1 represents perfect agreement; a precision value of 0 represents no agreement; and a precision value of −1 represents perfect negative agreement. Two-sided confidence limits for comparative precision are provided [Default: 95% two-sided confidence interval], precision tends to be greater than 90% for acceptable arrays.

Concordance Correlation

The concordance correlation is a reproducibility index that represents the correlation between signal responses between an experimental array versus the reference array. Pairs of signals that fall on the 45° line through the origin are said to be concordant. Relative to the reference the concordance index provides a measure of an array's accuracy, precision, location and scale shift. Concordance is the product of accuracy and precision, as previously defined. A concordance correlation coefficient of 1 represents perfect concordance with the internal reference. The further concordance is from 1, the greater the deviation from the 45° line through the origin. Concordance tends to be greater than 95% for acceptable arrays.

Calculations of concordance are performed on the natural logarithm scale. Under the assumption, of lognormality of signal response, concordance may be converted to standard units (z-score). Based on the z-score, the present invention calculates the probability of rejecting the hypothesis that concordance equals zero versus the alternative hypothesis that concordance is not equal to zero when in fact the hypothesis that concordance equals zero is actually true. The hypothesis of concordance equals zero should be rejected for small values of PR(CONCORDANCE), e.g., PR(CONCORDANCE)<5%. Two-sided confidence limits for concordance on the original scale are provided [Default: 95% two-sided confidence interval].

Minimum Detectable Fold Change

The minimum detectable fold change pertains to the smallest fold change that can reliably be considered as a change caused by a difference in signal response between two arrays. When the fold change is less than the minimum detectable fold change, however, it cannot be stated that a difference in signal response between the test and control samples does not exist. The present invention calculates the minimum detectable fold change based on a statistical criterion using statistical tolerance intervals (e.g., see http://www.qualityamerica.com/knowledgecente/articles/CQE_IIICb.html). [Default: 90% statistical tolerance limit for 90% of all array values]. The minimum detectable fold-change tends to be less than 2.5 for acceptable arrays.

Analytical Sensitivity

One of the fundamental characteristics of any analytical method is the smallest concentration that can be reliably measured. A number of terms and concepts have been used to describe the lowest concentration an array can report, and this multiplicity of terms can be genuinely confusing. The formal definition of analytical sensitivity is “the lowest concentration that can be distinguished from background noise.” This concentration is properly termed the assay's detection limit, but it is most commonly referred to as sensitivity. Typically, this value is established by assaying replicates of a sample that is known to have no analyte present. Frequently, microarray manufacturers report analytical sensitivity as the lowest concentration of a known signal that can be reproducibly detected. This concept is closely related to those of limit of detection and limit of quantitation.

The present invention produces the following estimates relating to the limits of detection and quantitation: threshold; limit of detectable signal response; limit of detection; limit of quantifiable signal response; and limit of quantitation.

Threshold

Thresholds for probe signals may be calculated as a factor of the standard deviation of the local background values for each probe. For example, thresholds may be calculated as three times the standard deviation of the local background values for each probe. Thresholds are a proxy for the limit of detectable signal response and are used to determine which probe signals are reported to end-users.

Limit of Detectable Signal Response

The limit of detectable signal response pertains to the smallest observed signal that with confidence level 100 (1−a) % can be considered as a signal caused by the input RNA measured. When the component is less than the limit of detectable signal response, however, it cannot be stated that the input RNA is absent. The present invention estimates the limit of detectable signal response based upon a 100 (1−a) % statistical tolerance limit for 100p% of all negative control (natural logarithm) signals. Two-sided confidence limits for the limit of detectable signal response are provided {Default: 95% two-sided confidence interval].

Limit of Detection

The present invention calculates the limit of detection (LOD) as the smallest amount of RNA/analyte that an array can reliably distinguish from negative control signals. More formally, it is the minimum true concentration of input RNA that produces a non-zero signal that can be distinguished at a specified level of confidence 100 (1−a) % from a non-zero probe signal produced by a negative control. When the component is less than the lower limit of detection, however, it cannot be stated that RNA transcription is absent. The estimated LOD is estimated using statistical calibration methods, based on the limit of detectable signal response. Two-sided confidence limits for limit of detection are provided [Default: 95% two-sided confidence interval].

Limit of Quantifiable Signal Response

The limit of quantifiable signal response is the smallest signal response that can be quantified with a pre-specified reliability. Unlike the limit of detectable signal response, the limit of quantifiable signal response ensures that with confidence level 100 (1−a)% the true signal level can be reliably distinguished from background. The present invention estimates the limit of quantifiable signal response based upon a 100 (1−a)% statistical tolerance limit for 100p% of all negative and low positive control (natural logarithm) signals, where p is the proportion of the population to be covered.

Limit of Quantitation

The limit of quantitation (LOQ) is the smallest amount of RNA/analyte that can be quantified with a pre-specified reliability. Unlike the limit of detection, the limit of quantitation ensures that with confidence level 100 (1−a) % of the true RNA concentration level can be reliably distinguished from background. The estimated LOQ is generated using statistical calibration methods based on the limit of quantifiable signal response [see LIMIT OF QUANTIFIABLE SIGNAL RESPONSE]. Two-sided confidence limits for the limit of quantitation are provided [Default: 95% two-sided confidence interval].

Linearity

The present invention performs statistical assessments of the linearity of the (natural logarithm) signal response of the positive control probes as a function of the (natural logarithm) input RNA/analyte concentrations for those probes. Given replicate positive control probe signals at one or more levels of input RNA concentrations, a lack of fit test may be performed to assess linearity. Alternatively, in the absence of replicate positive control probes, a partial F statistic may be calculated comparing the reduction in mean square error between a simple linear regression and quadratic polynomial regression model.

The present invention provides an estimate of the intercept obtained from the simple linear regression fit of (natural logarithm) positive control probe signal versus (natural logarithm) input RNA concentration. Two-sided confidence limits for the intercept are provided [Default: 95% two-sided confidence interval].

An estimate of the slope obtained from the simple linear regression fit of (natural logarithm) positive control probe signal versus (natural logarithm) input RNA concentration is also calculated.. Two-sided confidence limits for slope are provided [Default: 95% two-sided confidence interval].

An estimate of the mean squared error obtained from the simple linear regression fit of (natural logarithm) positive control probe signal versus (natural logarithm) input RNA concentration is also calculated, according to known techniques for determining such.

Further, the present invention may provide an estimate of the mean squared error obtained from the quadratic polynomial regression fit of (natural logarithm) positive control probe signal versus (natural logarithm) input RNA concentration. A partial F statistic may be calculated for testing the null hypothesis that the quadratic term in a quadratic polynomial regression model is zero versus the alternative that the quadratic term is non-zero. Further, the probability of rejecting the hypothesis of linearity when the hypothesis is actually true (i.e., PR(F)) may be calculated. The hypothesis of linearity should be rejected for small values of PR(F), e.g., less than about 5%.

Dynamic and Linear Dynamic Range

Dynamic Range

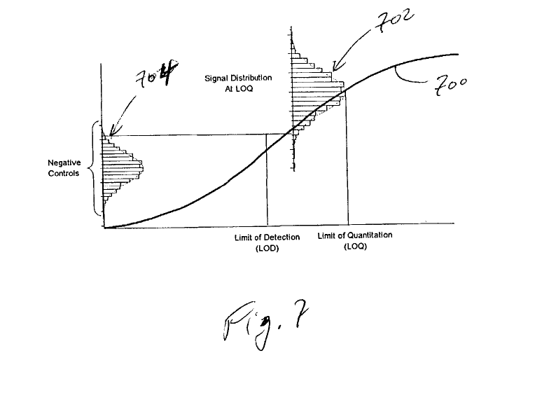

The dynamic range of an array is the interval between the upper and lower RNA/analyte concentration in the sample (including these concentrations) for which it has been demonstrated that the array has a suitable level of precision and accuracy. The full dynamic range of the array typically includes “nonlinear” regions in which signal response is not proportional to RNA/analyte concentration, but which still contains detectable (and often quantifiable) signal responses. The present invention estimates the dynamic range based upon the upper and lower limits of detection obtained from estimates of the sigmoidal logistic calibration curve generated from the positive and negative control probes. The dynamic range is limited at the lower end by the value of (natural logarithm) concentration of input RNA/analyte where the signal response cannot be distinguished from the noise in the signal response. The upper limit of the dynamic range is typically determined by the saturation point of the scanner detector. The Marquardt-Levenberg method is used to fit the four-parameter sigmoidal logistic function of the logarithm of the signal versus the logarithm of the concentration data of the control data. An example of such a fit is shown by curve 600 in FIG. 6. The Marquardt-Levenberg method is described in more detail in co-pending commonly owned Application (serial no. not yet assigned, Attorney's Docket No. 10030281-2) filed Mar. 27, 2003 and titled “Method and System for Predicting Multi-Variable Outcomes”.

Error bars for the sigmoid are determined by the error distribution, and it is desirable that the probability of the error being outside those values is small. Good precision implies that the error bars are small or tight to the sigmoid curve. FIG. 7 shows an example of imposition of error bars 702 on sigmoid 700. Error bars 702 are errors for positive values (i.e., the signal desired to be used) Error bars 704 may also be imposed for negatives, i.e., background error.

Linear Dynamic Range

In contrast, the linear dynamic range of an array is the interval between the upper and lower RNA/analyte concentration levels in the sample (including the highest and lowest concentrations) for which it has been demonstrated that the array has a suitable level of precision, accuracy and linearity. The additional constraint of linearity is often desirable to the researcher due to the simplification it provides in the interpretation of results. The present invention estimates the linear dynamic range based upon the parameter estimates obtained from the estimated calibration curve generated from the positive and negative control probes. The present invention also provides the starting and ending points of the linear dynamic range (START OF LINEAR RANGE and END OF LINEAR RANGE).

Signal Response Range

The signal response range pertains to the interval in (natural logarithm) signal response for which it has been demonstrated that the array has a suitable level of precision and sensitivity.

Quality Control Metrics

Statistical Calibration

The present invention utilizes the negative and positive control probes of an array for both quality control and calibration purposes. Calibration pertains to the problem of estimating an unknown analyte /RNA concentration based on an observed probe signal known to be functionally related to the (unknown) input analyte/RNA concentration. The present invention models a generalized form of the four-parameter logistic model, with a variance function related to the mean signal response. The logistic technique is the most popular semi-empirical model used in the analysis of bioassays. The four-parameter logistic response curve is symmetric and sigmoidal in shape, as shown in FIG. 6.

Using the four-parameter logistic calibration curve as described, the present invention may provide estimates of the lower asymptote of the curve in the model, the upper asymptote, the center or inflection point, the slope and/or the mean squared error. The lower asymptote of the four-parameter logistic calibration curve may be estimated along with Two-sided confidence limits [Default: 95% two-sided confidence interval].

Similarly, the upper asymptote of the four-parameter logistic calibration curve may be estimated along with Two-sided confidence limits [Default: 95% two-sided confidence interval].

The present invention provides the capability for estimates and Two-sided confidence limits of the center or inflection point of the four-parameter logistic calibration curve [Default: 95% two-sided confidence interval]. The inflection point corresponds to the effective concentration on the curve where 50% signal response is obtained (i.e., the Ec₅₀)

An estimate of the slope of the four-parameter logistic calibration curve along with Two-sided confidence limits [Default: 95% two-sided confidence interval] may also be provided. Further, an estimate of the mean squared error, or average error, generated by the fitted four-parameter logistic calibration curve may be provided.

Asymmetry in Signal Response

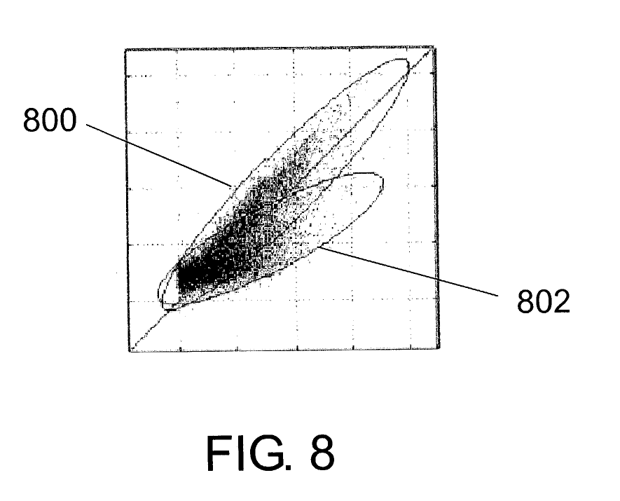

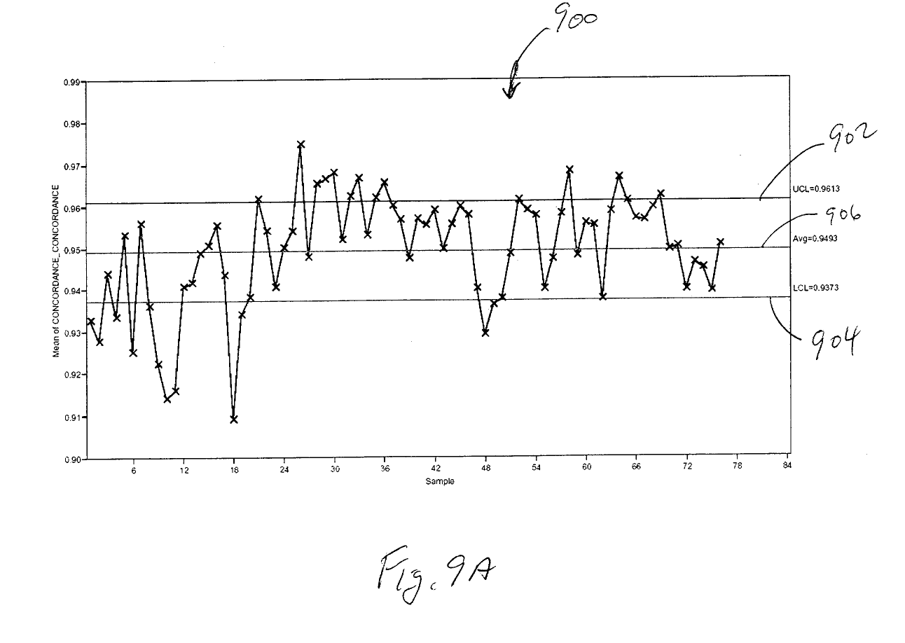

To some extent distortions in symmetric distributions such as Gaussian populations are expected in gene-expression comparisons, since excitation may require more energy versus ambient activity. However, when comparing signal responses between a test array and a reference array, a researcher may observe subpatterns of probe signal responses that exhibit abnormal behavior. These subpatterns are sometimes indicative of process deviations. For example the Motorola array puts high abundance genes on one end of the array going to low abundance genes on the opposite end. If there is a scanner shift, HYB discontinuity, or printer shift at any location along the array, the result is a break in the plotted ellipsoidal pattern. Corrective action should be taken immediately to isolate and remove such process deviations. As illustrated in FIG. 8, such sub-array populations 802 are easy to identify visually with the aid of a reference array 800. However, without the benefit of a reference array set, producing such plots for signal channel arrays is difficult.

As a result, such effects are often overlooked. The present invention provides a series of metrics for assessing asymmetry. Asymmetry effectively measures the difference in the proportion of pairs of signal responses on either side of the 45° line (i.e., the concordance line). Under the assumption of symmetry, the proportion of pairs of signal responses on either side of the concordance line should remain equal. Asymmetry should be near zero, although slight positive asymmetry is often observed in practice.

Summary Statistics for Control Probes and Complex Sample

The present invention provides a number of classical and robust summary statistics for each positive and negative quality control probe as well as for complex sample (e.g., a real biological sample; sample from the target organism).

Mean Signal Response

The mean (natural logarithm) signal response is a measure of the central signal response. Two-sided confidence limits are provided [Default: 95% two-sided confidence interval]. Users may have the option of generating either classical or robust estimates of the mean signal response.

Standard Deviation in Signal Response

The standard deviation of (natural logarithm) signal response is a measure of the spread in signal responses for an array. Standard deviations are useful for comparing signal responses across different sets of arrays when expressed in standard units. Standard units, also known as standard scores, or z-scores, tell the user how many standard deviations an item is above or below the mean of the set of data to which it belongs. The standard deviation of signal response on the natural logarithm scale can be shown mathematically to be an excellent approximation to the coefficient of variation of signal response on the original scale for array data. Two-sided confidence limits are provided [Default: 95% two-sided confidence interval]. Users may have the option of generating either classical or robust estimates of the standard deviation of signal response.

A classical estimate may be obtained according to the formulae provided above with regard to standard deviation and confidence intervals. There are no closed form expressions for the robust mean and standard deviation. Estimates for the robust mean and robust standard deviation are obtained using iterative algorithms, as described in http://www-sop.inria.fr/robotvis/personnel/zzhang/Publis/Tutorial-Estim/node24.html and Peter J. Huber's book Robust Statistics (referenced above). Confidence limits for robust cases are computed identical in form to the classical case, with the only difference being that the robust mean is used instead of the classical mean, and the robust standard deviation is used instead of the classical standard deviation.

Coefficient of Variation of Signal Response

The coefficient of variation of (natural logarithm) signal response is simply the standard deviation of (natural logarithm) signal response expressed as a percentage of the average (natural logarithm) signal response. The coefficient of variation is a measure of the relative variation in signal response. Two-sided confidence limits are provided [Default 95% two-sided confidence interval]. Users may have the option of generating either classical or robust estimates of the coefficient of variation of signal response.

Skewness

Skewness is a measure of a lack of symmetry in the distribution of the data values in a data set. A distribution, or data set, is symmetric if it looks the same to the left and right of the center point. For the normal distribution, the expected value for skewness is zero, indicating symmetry. For the lognormal distribution, skewness is a function of the mean and variance of the distribution. Larger values of skewness indicate the lack of symmetry in the data. These are heuristic measurements. Skewness refers to how far the data are from being symmetric. For example, the scale for skewness may be set up so that perfect symmetry has a value of 1 and complete asymmetry has a value of 0, or vice versa.

Kurtosis

Kurtosis is a measure of whether the data are peaked or flat relative to a normal distribution. That is, data sets with high kurtosis tend to have a distinct peak near the mean, decline rather rapidly, and have heavy tails. For the normal distribution, the expected value for kurtosis is 3. Low values of kurtosis indicate that the data set tends to have a flat top near the mean rather than a sharp peak. A uniform distribution would be the extreme case.

Statistical Process Control

Quality control (QC) metrics may be control-charted over time as a means of process control. This enables the user to quickly identify process shifts and trends. Control-charting methods are based on continuous monitoring of process variations. Control charts have three basic components: (a) a centerline, usually the mathematical average of all the samples plotted, (b) upper and lower statistical control limits that define the constraints of common cause variations and (c) performance data plotted over time. Control charts are generated to look at variation, seek special causes of variation, and/or track common causes of variation. Special causes can be spotted using one or more of several tests. One test triggers when one data point falls outside predefined control limits. Another test triggers when six or more points in a row are steadily increasing or steadily decreasing in value. Another test identifies variation when eight or more points in a row are displayed on one side of the centerline of the chart. Another test triggers when it identifies fourteen or more points alternating up and down in value.

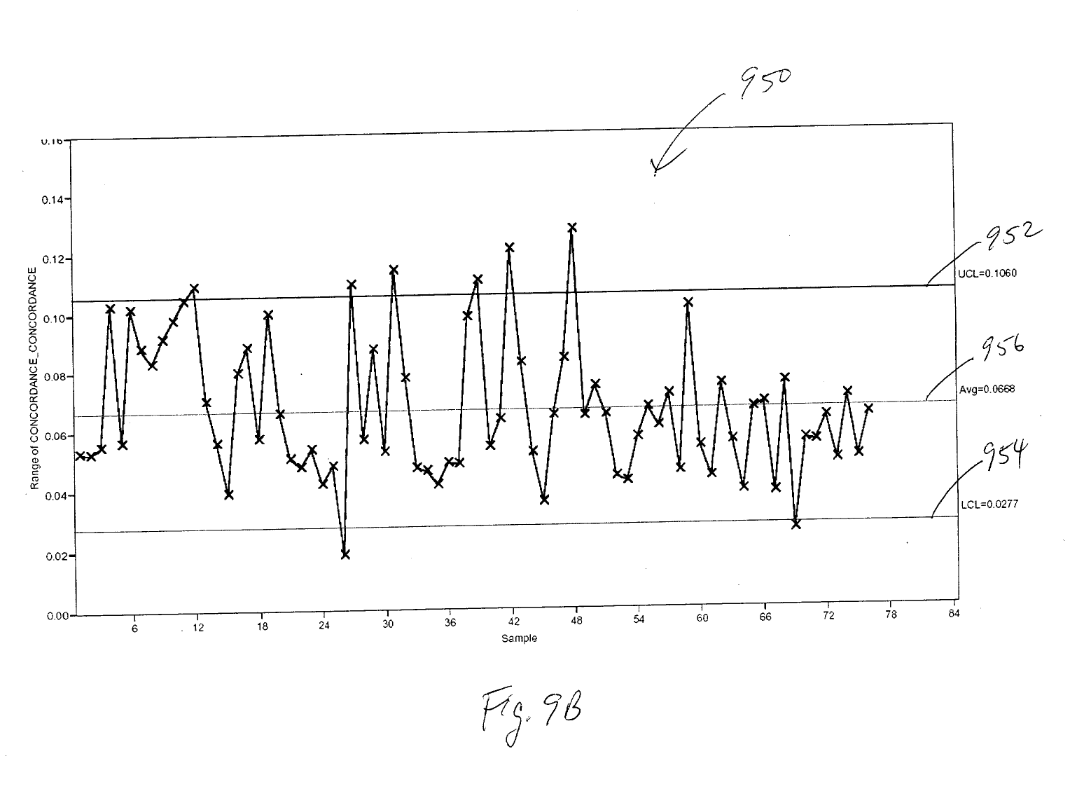

Charts may be paired together, in which case the user will look for anomalies of the types described in both charts. For example, FIGS. 9A and 9B show an example of a pair of charts, in which chart 900 plots the process average, which in this example is the mean of the concordance. The upper limit for normal processing is line 902 (UCL) which is the statistically-derived upper confidence limit. The lower limit for normal processing 904 (LCL) is a line identifying the statistically-derived lower confidence limit. Line 906 denotes the average of the range. As long as the plotted data points are within the bounds defined by lines 902 and 904, the process is operating normally. Any points that land outside this range identify unusual events, signaling that the process should be checked out and corrected. FIG. 9B plots the variability or range of a metric being used, in this example, the range of concordance. The upper limit for normal processing is line 952 (UCL) which is the statistically-derived upper confidence limit. The lower limit for normal processing 954 (LCL) is a line identifying the statistically-derived lower confidence limit. Line 956 denotes the average of the range. As long as the plotted data points are within the bounds defined by lines 952 and 954, the process is operating normally. Any points that land outside this range identify unusual events, signaling that the process should be checked out and corrected.

The simplest interpretation of the control charts is to use only the test which identifies when a data point falls outside predefined control limits. The other tests may be useful, although it is noted that as more tests are applied, the chances of making Type 1 errors (i.e. getting false positives), go up significantly. Control limits on a control chart are commonly drawn at 3-sigma (i.e., three times the standard deviation) from the center line because 3-sigma limits are a good balance point between two types of errors: Type I errors occur when a point falls outside the control limits even though no special cause is operating. The result is a witch hunt for special causes. The tampering usually distorts a stable process as well as wasting time and energy. Type II errors occur when a special cause is missed because the chart isn't sensitive enough to detect it. In this case, the user is unaware that the problem exists and thus unable to root it out. All process control is vulnerable to these two types of errors. The use of 3-sigma control limits balances the risk of error. That is, for normally distributed data, data points will fall inside 3-sigma limits 99.7% of the time when a process is in control. This makes the witch hunts infrequent but still makes it likely that unusual causes of variation will be detected.

Automatic Classification and Quality Scoring

Bioassays tend to be very complicated processes impacted by a host of variable factors including nuisance and noise effects. Quality assurance of such a process requires constant vigilance and evaluation of performance and parameter patterns. Typically, a trained expert of the bioassay must perform the duties of evaluation of performance and parameter patterns. For large-scale operations these tasks become very expensive if done manually and inevitably lead to human errors and inconsistencies.

The present invention emulates the performance of such a trained expert through the use of data analysis and modeling programs. The present system may be first trained on a comprehensive and representative reference population of array results, and then applied online to quality control the assay performance in large-scale production mode. For each array the parameter patterns are converted into a quality control (QC) score that is scaled from poor to high quality. A QC score of zero indicates a marginal performance and requires manual review for further classification. A QC score of negative one (−1) represents a failed array while a QC score of positive one (1) represents a good array. Additionally, if the pattern is outside the scope of the reference training population, the array is marked for manual evaluation and added to the reference population. This is similar to an expert encountering an unusual pattern that he needs to learn to enhance his training. Thus, a goal of automatic classification according to the present invention is to determine whether a previously unexamined array is “good” (e.g., recommended as having sufficient reliability for use) or “bad” (e.g., not recommended to be relied upon). The fact that the present system can train upon inspection results produced by one or more human professionals offers an advantage, in that, when trained upon more than one professional's results, this gives the system the capability of providing what is essentially a consensus of results, as would occur with inspection by a panel of experts. Additionally, the present system is able to inspect arrays in high dimensional space, in view of any or all of the metrics discussed above. While human inspectors are very good at inspecting in up to three dimensions, it becomes increasingly more difficult, if not impossible, to formulate comparison among metrics of four and more dimensions.

As part of the quality scoring process, the present invention utilizes a combination of a very simple model and a complex model. The simple model is very stable and extends well to new data. However, the simple model cannot represent the complexity of combinatorial effects that tend to characterize bioassays in general. The complex model, referred to as a predictor-corrector method, reliably extends the simple model to an expert status. In process control terms, the predictor-corrector method is a feed-forward control process to correct errors made by the simple model. Standard statistical methods are used to assign probabilities to each of the three classes based on the quality-control (QC) score. The highest probability determines QC class. This is similar in strategy to the fuzzy logic technology that has proven successful at solving large-scale control problems. Examples of predictor-corrector methods are described in commonly owned Application (serial no. not yet assigned, Attorney's Docket No. 10030281-2) filed Mar. 27, 2003 and titled “Method and System for Predicting Multi-Variable Outcomes”, and in U.S. Pat. No. 6,188,969, although the methods described in U.S. Pat. No. 6,188,969 are not capable of performing ordinal regression.

An automatic classification and quality scoring system according to the present invention is designed to first train on a set of arrays that have been previously inspected and scored by one or more human professional inspectors. These arrays are also processed by the present invention for de-trending and de-warping according to the techniques described above. A profile is generated for each of the previously inspected arrays. Along with the scores assigned by the human professional inspectors, any or all of the metrics described above may be incorporated into each profile. For example, estimated parameters from de-trending, estimated parameters from de-warping, metrics taken before and after de-warping and/or delta metrics, and any of metrics for accuracy, precision, analytical sensitivity, linearity and dynamic and linear dynamic range may be included.

Among accuracy metrics, metrics for accuracy, location shift and/or scale shift may be considered. Among precision metrics, metrics for standard deviation of signal response, coefficient of variation of signal response, comparative precision (Pearson's correlation), concordance correlation, and/or minimum detectable fold change may be considered. Analytical sensitivity metrics that may be inserted include threshold, limit of detectable response, limit of detection, limit of quantifiable signal response, and/or limit of quantitation. Linearity metrics that may be inserted include intercept for linear model, slope for linear model, means squared error for linear model, mean squared error for quadratic model, and/or partial F-statistic. Dynamic and linear dynamic range metrics that may be inserted into the model include dynamic range, linear dynamic range, and/or signal response range.

Statistical calibrations that may be inserted include lower asymptote, upper asymptote, EC₅₀, slope and/or mean squared error. Asymmetry in signal response may also be included in the profile. Summary statistics for control probes and complex sample may be inserted in the profile, including mean signal response, standard deviation in signal response, coefficient of variation of signal response, skewness and/or kurtosis. Robust estimation metrics may be inserted, including simultaneous M-estimators of location and scale. Statistical process control may be employed to control-chart quality control metrics over time. Any and all of the other statistical methods discussed above may be employed to derive metrics that are inserted into the profile for each array to be classified.

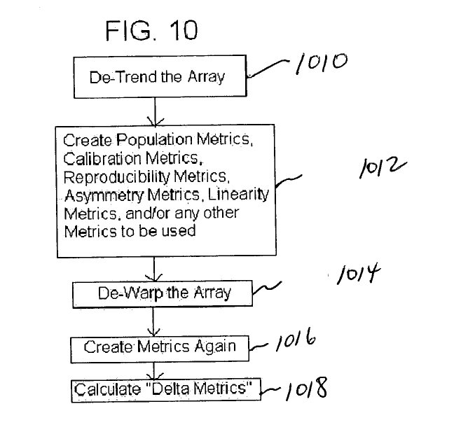

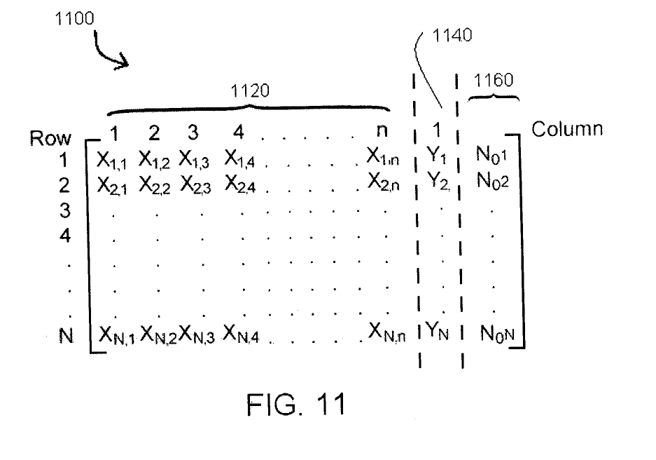

FIG. 10 shows general process steps performed in preparing an automatic classification and quality scoring system according to the present invention. Starting with a training set (e.g., reference arrays that have been previously classified by an expert inspector of panel of expert inspectors), each array is processed according to these steps to develop the profiles to be used by the automatic classification and quality scoring system. For simplicity, processing steps for only the first array in the training set will be described here. However, each array in the training set will be processed similarly, to develop a profile for each respective array.

The array is de-trended at step 1010, to remove non-biological biological distortions, as described above. This step removes blocking effects, if any, as well as global and localized trending patterns caused by manufacturing processes during the manufacture of the chip on which the biological material has been placed.

After de-trending, the system creates any or all of population metrics, calibration metrics, reproducibility metrics, asymmetry metrics, linearity metrics, and/or any of the other previously-described metrics to be considered in the particular model for automatic classification and quality scoring. These metrics are then stored for later use.

Next, the array is de-warped, according to the techniques described above, so as to align the inert genes with the concordance line. As noted above, de-warping is performed on a two-channel basis, e.g., red versus green channels, or a single channel color versus a reference array, such as the so-called “perfect array” that is an average, such as a robust average, over many arrays that have been empirically determined to be “good” arrays.

After de-warping, so as to eliminate or reduce bias toward one or the other channel, at step 1016 the same metrics are again produced as were produced in step 1012, except that they are generated this time on the de-warped signals. Again the metrics are stored. At step 1018, “delta metrics” are calculated. Delta metrics are defined as the difference between corresponding metrics values generated in step 1012 as compared to those generated in step 1016.

Once all of the arrays to be used in the training set have been processed according to the above, a matrix of profiles is generated, wherein the matrix contains a row of values for each representative array, wherein each row corresponds to the profile of that array. For example, the profiles may contain values for the estimated parameters from de-trending, estimated values from de-warping, metrics created after de-trending, metrics created after de-warping and delta metrics. These will be referred to as “x-values” for purposes of discussion during the next phase of processing. Additionally, since the arrays at this stage have already been previously classified by human inspector(s), there are score values (e.g., pass, fail or marginal) that have been assigned to the arrays. These values will be referred to as “y-values” for purposes of discussion during the next phase of processing. Since there are more than two possible classification categories, the present invention may assign multiply-y logistic distribution to the y-profile, or assign an ordinal regression distribution to the classifications. Optionally, the classes may be partitioned into a first group that is suitable for logistic probabilities and a second group that is suitable for ordinal scaling probabilities.

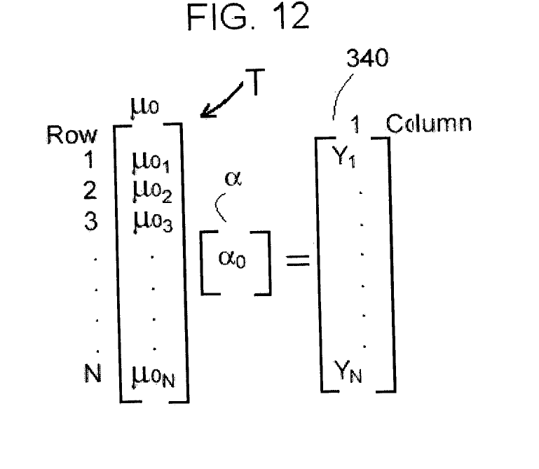

Referring now to FIG. 11, an example of formulating a predictor-corrector model for automatic classification and quality scoring continues. The profiles (x-values) 1120 for each array are arranged in a matrix 1100 adjacent the scores for the arrays (y-values) 1140 and also a noise profile 1160. Noises are like hidden variables. Noises are ever present but it is not known how to extract the values of these variables. All inference models must accommodate noise. Hence, the Nₒ-values (noise) represent the noise values associated with each row (array). The left-side 1120 of the rows of matrix 1100, which are populated by the X variables in FIG. 11 define the profiles of the arrays and the right-side (1140, 1160) of the rows of matrix 1100, which are populated by the quality scores (Y-values) and Nₒ variables in FIG. 11 define the Y-profile and noise associated with the rows.

Each row of matrix 1100 may be treated as a data object, i.e., an encapsulation of related information. The present system analyzes these objects and compares them with some measure of similarity (or dissimilarity). A fundamental underlying assumption of this methodology is that if the X values are close in similarity, then the Y-values associated with those rows will also be close in value. By processing the objects in the matrix 1100, a similarity transform matrix may be constructed using similarity values between selected rows of the X-profile, as will be described in more detail below. The X-profile objects (rows) are used to determine similarity among one another to produce similarity values used in the similarity transform matrix. Similarity between rows may be calculated by many different known similarity algorithms, including, but not limited to Euclidean distance, Hamming distance, Minkowski weighted distance, or other known distance measurement algorithms. The normalized Hamming function measures the number of bits that are dissimilar in two binary sets. The Tanimoto or Jaccard coefficient measures the number of bits shared by two molecules relative to the ones they could have in common. The Dice coefficient may also be used, as well as similarity metrics between images or signal signatures when the input contains images or other signal patterns, as known to those of ordinary skill in the art.

With any set of data being analyzed, such as the data in matrix 1100, for example, it has been found that certain, select X-profiles among the objects are more critical in defining the relationship of the function sought than are the remainder of the X-profiles. Thus, in this example, the system solves for these critical profiles that give critical information about the relationship between the X values and the Y values.

To solve for the critical profiles, an initial model (called Model Zero (Model 0) is inputted to the system, in matrix T (See FIG. 12). Model Zero (designated as μ₀ in FIG. 12), may be a conventional model, conceptual model, theoretical model, an X-profile with known Y-profile outcomes, or some other reasonable model which characterizes a rough approximation of the association between the X- and Y-profiles, but still cannot explain or account for a lot of systematic patterns effecting the problem. Model Zero is the “simple model” referred to above. Thus, Model Zero predicts Y (i.e., the Y values in the Y-profile), but not adequately. Alternatively, a null set could be used as Model Zero, or a column of equal constants, such as a column with each row in the column being the value 1 (one).

A least squares regression algorithm (or other regression algorithm) is next performed to solve for the coefficient α₀₁ (since the “Y-matrix” is a vector in this case, the o matrix is a scalar, see FIG. 12) which will provide a best fit for the use of Model Zero to predict the Y-profiles, based on the known quantities in matrix μ₀ and matrix 1120. It should be noted here that this step of the present invention is not limited to solving by least squares regression. Other linear regression procedures, such as median regression, ordinal regression, distributional regression, survival regression, or other known linear regression techniques may be utilized. Still further, non-linear regression procedures, maximum entropy procedures, mini-max entropy procedures or other optimization procedures may be employed. Solving for the α₀ matrix α optimizes Model Zero to predict the Y-profile 1140. Then the prediction errors (residuals) are calculated as follows:

Y−(T19 α)=ε (22)

where

Y=matrix 1120;

α=α matrix (which is a scalar in the example shown in FIG. 12);

T=the T matrix (i.e., vector, in this example, although the Model Zero profile may be a matrix having more than one column); and

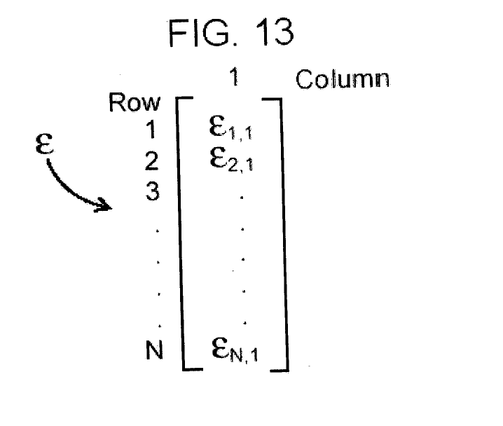

ε=error matrix , or residuals (which is a vector in this example, see FIG. 13) characterizing Model Zero with ε₀ values.

The error matrix (vector) ε resulting from processing, using the example shown in FIG. 12. Next, the system determines the row of the ε matrix (which in this case is a single value, since the ε matrix is a vector) which has the maximum absolute value of error. Note that for problems where the Y-profile is a vector (i.e., an N×1 matrix, i.e., where M=1), the error matrix ε will be a vector (i.e., an N×1 matrix) and the maximum absolute error can be easily determined by simply picking the largest absolute value in the error vector. For examples where the error matrix ε is an N×M matrix, different options are available, such as picking the maximum absolute error value from the entire set of values displayed in matrix ε, constructing an ensemble error for each row of error values in matrix ε and picking the largest absolute ensemble error, etc.

In this example, however, the largest absolute error value is simply picked. The row from which the maximum absolute error is located is noted and used to identify the row (X-profile) from matrix 1120, from which similarity values are calculated. The calculated similarity values are used to populate the next column of values in the matrix containing Model Zero. For example, at this stage of the processing, the similarity values will be used to populate the second column of the matrix, adjacent the Model Zero values. However, this is an iterative process which can be used to populate as many columns as necessary to produce a “good or adequate fit”, i.e., to refine the model so that it predicts Y-profiles within acceptable error ranges. An acceptable error range will vary depending upon the particular problem that is being studied, and the nature of the Y-profiles. For example, a model to predict temperatures may require predictions within an error range of ±1° C. for one application, while another application for predicting temperature may require predictions within an error range of ±0.01° C. That is to say, that this system is not limited to predicting quality scores for microarrays, but is readily adaptable to customize a model to meet the required accuracy of the predictions that it produces.

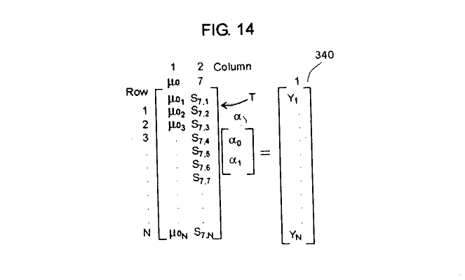

Assuming, for exemplary purposes, that the row from which the maximum absolute error was found in matrix (vector) ε was the seventh, the system then identifies the seventh row in matrix 1120 to perform the similarity calculations from. Similarity calculations are performed between the seventh X-profile and each of the other X-profile rows, including the seventh row X-profile with itself. For example, the first row similarity value in column 2, FIG. 14 (i.e., S_{7,1}) is populated with the similarity value calculated between rows 7 and 1 of the X-profile matrix 1120. The second row similarity value in column 2, FIG. 14 is populated with the similarity value S_{7,2}, the similarity value calculated between rows 7 and 2, and so forth. Note that row 7 is populated with a similarity value calculated between row 7 with itself. This will be the maximum similarity value, as a row is most similar with itself and any replicate rows. The similarity values may be normalized so that the maximum similarity value is assigned a value of 1 (one) and the least similar value would in that case be zero. As noted, row 7 was only chosen as an example, but analogous calculations would be performed with regard to any row in the matrix 1120 which was identified as corresponding to the highest maximum absolute error value, as would be apparent to those of ordinary skill in the art. It is further noted that selection does not have to be based upon the maximum absolute error value, but may be based on any predefined error or ensemble error scoring. For example, an average or ensemble average absolute error, median or ensemble median absolute error, mode or ensemble mode absolute error, weighted average or ensemble weighted average absolute error, robust average or ensemble robust average absolute error, geometric average divided by standard deviation of errors, geometric average, ensemble error divided by standard deviation of errors of ensemble, or other predefined absolute error measure may be used in place of the maximum absolute error or maximum ensemble absolute error.

The X-profile row selected for calculating the similarity values marks the location of the first critical profile or “tent pole” identified by the system for the prediction model. A least squares regression algorithm is again performed next, this time to solve for coefficients α₀ and α₁ in the matrix α which results from this iteration. Note, that since the T matrix is now an N×2 matrix, that matrix α needs to be a 2×M matrix ( in this case, a 2×1 vector, since M=1), where the first row is populated with the α₀ coefficients (i.e., α_{0 1,1}, α_{0 1,2}, . . . α_{0 1,M}), and the second row is populated with the oil coefficients (i.e., α_{1 1,1}, α_{1 1,2}, . . . α_{1 1,M}). The α₀ coefficients that were calculated in the first iteration using only Model Zero are discarded, so that new α₀ coefficients are solved for, along with α₁ coefficients. These coefficients will provide a best fit for the use of Model Zero and the first tent pole in predicting the Y-profiles. After solving for the coefficients in matrix α, the prediction errors (residuals) are again calculated, using equation (24), where α is a 2×M matrix in this iteration, and T is an N×2 matrix. Each row of α may be considered a transform of the rows of Y. For linear regression, this transformation is linear.

Again, the system determines the row of the ε matrix which has the maximum absolute value of error, in a manner as described above. Whatever technique is used to determine the maximum absolute error, the row from which the maximum absolute error is noted and used to identify the row (X-profile) from matrix 1120, from which similarity values are again calculated. The calculated similarity values are used to populate the next column of values in the T matrix (in this iteration, the third column), which identifies the next tent pole in the model. The X-profile row selected for calculating the similarity values marks the location of the next (second, in this iteration) critical profile or “tent pole” identified by the system for the prediction model. A least squares regression algorithm is again performed, to perform the next iteration of the process, as described above. The system can iterate through the above-described steps until the residuals come within the limits of the error range desired for the particular problem that is being solved, i.e., when the maximum error from matrix ε in any iteration falls below the error range. An example of an error threshold could be 0.01 or 0.1, or whatever other error level is reasonable for the problem being addressed. With each iteration, an additional tent pole is added to the model, thereby reducing the prediction error resulting in the overall model.

Alternatively, the system may continue iterations as long as no two identified tent poles have locations that are too close to one another so as to be statistically indistinct from one another, i.e., significantly collinear. Put another way, the system will not use two tent poles which are highly correlated and hence produce highly correlated similarity columns, i.e., which are collinear or nearly collinear (e.g., correlation squared (R²)>95%, of the two similarity columns produced by the two X-profiles (tent pole locations). However, even if an X-profile is dissimilar (not near) all selected profiles in the model, it may still suffer collinearity problems with columns in the T-matrix as is. Hence, a tent-pole location is added to the model only if it passes both collinearity filters.

When a tent pole (row from matrix 1120) is identified from the maximum absolute error in an E matrix that is determined to be too close (nearly collinear) to a previously selected tent pole, the system rejects this choice and moves to the next largest maximum absolute error value in that E matrix. The row in matrix 1140 which corresponds to the next largest maximum absolute error is then examined with regard to the previously selected tent poles, by referring to the similarity column created for each respective selected X-profile. If this new row describes a tent pole which is not collinear or nearly collinear with a previously selected tent pole, then the calculated similarity values are inserted into a new column in matrix T and the system processes another iteration. On the other hand, if it is determined that this row is nearly collinear or collinear with a previously chosen tent pole, the system goes back to the ε matrix to select the next highest absolute error value. The system iterates through the error selection process until a tent pole is found which is not collinear or nearly collinear with a previously selected tent pole, or until the system has exhausted all rows of the error matrix ε. When all rows of an error matrix ε have been exhausted, the model has its full set of tent poles and no more iterations of the above steps are processed for this model.

The last calculated α matrix (α profile from the last iteration performed by the system) contains the values that are used in the model for predicting the Y-profile with an X-profile input. Thus, once the system determines the critical support profiles and the α values associated with them, the model can be used to predict the Y-profile for a new X-profile. In this example, once the system has determined the computer functional relationship between the array profiles and the quality scores assigned to them by human inspector(s), then this functional relationship can be used to automatically classify and quality score arrays which have not been previously inspected by humans.

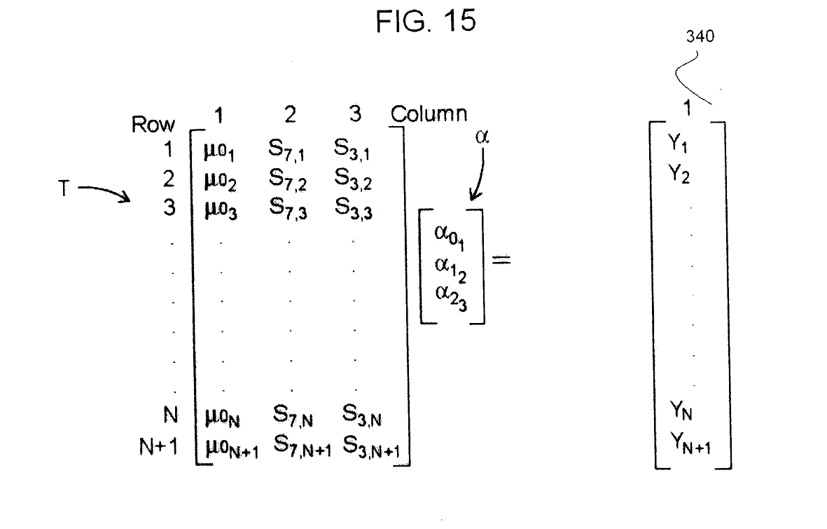

Referring now to FIG. 15, an example is shown wherein a new array (i.e., X-profile N+1) has been inputted to the predictor model in order to automatically classify and quality-score the array (i.e., determined the Y-Profile or Y-value). For simplicity of explanation, this example uses only two tent poles, together with Model Zero, to characterize the predictor model. In practice, there will generally be many more tent poles employed. As a result, the α matrix in this example is a 3×M matrix (i.e., 3×1 vector), as shown in FIG. 15, and we have assumed, for example's sake, that the second profile is defined by the third row X-profile of the X-profile matrix 1120. Therefore, the similarity values in column 3 of matrix T are populated by similarity values between row three of the X-profile matrix 1120 and all rows in the X-profile matrix 1120.

Again for simplicity, the example uses only a single uninspected array (i.e., the N+1^{st} X-profile), so that only a single row is added to the X-profile 1120, making it an (N+1)×n matrix, with the N+1^{st} row being populated with the profile values of the uninspected array, although the present invention is capable of handling multiple rows of X-profiles simultaneously, as would be readily apparent to those of ordinary skill in the art in view of the above description.

Because the X-profile matrix has been expanded to N+1 rows, Model Zero in this case will also contain N+1 components (i.e., is an (N+1)×1 vector)) as shown in FIG. 15. The tent pole similarity values for tent poles one and two (i.e., columns 2 and 3) of the T matrix are populated with the previously calculated similarity values for rows 1−N. Row N+1 of the second column is populated with a similarity value found by calculating the similarity between row 7 and row N+1 (i.e., the profile of the uninspected array) of the new X-profile matrix 1120. Similarly, Row N+1 of the third column is populated with a similarity value found by calculating the similarity between row 3 and row N+1 (i.e.,. the uninspected array profile) of the new X-profile matrix 1120.

The system then utilizes the α matrix to solve for the Y_{N+1} profile using the X_{N+1} profile using the following equation:

T·α=Y+ε (23)

where, for this example,

T=the N+1^{st} row of the T matrix shown in FIG. 15,

α=the α matrix shown in FIG. 15,

Y=the N+1^{st} row of the matrix 1140 shown in FIG. 15,

ε=a vector of M error values associated with the Y-profile outcome.

The error values will be within the acceptable range of permitted error designed into the predictor model according to the iterations performed in determining the tent poles as described above.

Typically, this method overfits the data, i.e., noise are fit as systematic effects when in truth they tend to be random effects. The predictor model is therefore trimmed back to the minimum of the sum of squared prospective ensemble errors to optimize prospective predictions, i.e., to remove tent poles that contribute to over fitting of the model to the data used to create the model, where even the noise associated with this data will tend to be modeled with too many tent poles.

By processing according to the predictor model, arrays previously uninspected by human inspectors can have a profile developed (according to the processing steps described above with reference to FIG. 10), and these profiles can be used to determine classification scores. The present system converts the profiles into linear scored which can be used to assign probabilities to the classes developed. The scoring system separates classes, based upon the learning achieved through processing reference arrays having been previously inspected by humans and scored. The classes are assigned probabilities, and whichever class has the highest probability is the class that the array is scored as. The scoring system can be one dimensional or multidimensional. Currently ordinal regression is used in a one dimensional format to classify the array as a pass or a fail. If a result is not distinctly separated between the division of the pass and fail classes, the array is assigned a marginal classification, meaning that further inspection, most likely by a human inspector, is in order.

In general, once a model is determined, as described above, the Z-columns of distribution-based U's are treated as linear score functions where the associated distribution, such as the binomial logistic model, for example, assigns probability to each of the score values.

The initial such Y-score function is estimated by properties of the associated distribution, e.g., for a two-category logistic, assign the value +1 for one class and the value −1 for the other class. Another method uses a high-order polynomial in a conventional distribution analysis to provide the score vector. The high order polynomial is useless for making any type of predictions however. The model according to the present invention predicts this score vector, thereby producing a model with high quality and effective prediction properties. The model can be further optimized by using the critical S-columns of the similarity matrix directly in the distributional optimization that could also include conventional X-variables and/or Model Zero. Hence, the model provides a manageable set of high-leverage terms for distributional optimizations such as provided by generalized linear, mixed, logistic, ordinal, and survival model regression applications. In this fashion, this modeling method is not restricted to univariate binomial logistic distributions, because it can predict multiple columns of Y (in the Y-profile 1140). Thus, the model can simultaneously perform logistic regression, ordinal regression, survival regression, and other regression procedures involving multiple variable outcomes (multiple responses) as mediated by the score-function device.

Thus, from the training set, the system learns to associate profiles with categories/classes having been assigned to those profiles by an inspector. From this, the system can examine a profile that has not had a category/class assigned to it, and classify based on prior learning regarding the relationships between profile values and classification outcomes.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

That which is claimed is:

1. A method of removing nuisance distortions from array data, said method comprising the steps of:
inputting signals generated from reading an array containing biological data;
applying at least one algorithm to the inputted signals to estimate and remove at least one nuisance distortion from the signals representing the array data; and
outputting signals representative of the biological data after removal of the at least one nuisance distortion.

2. The method of claim 1, wherein the biological data comprises biological information or content of interest in an experiment, and wherein signals representative of the biological data are retained in the outputted signals.

3. The method of claim 1, wherein said applying at least one algorithm to estimate and remove comprises de-trending.

4. A method comprising forwarding a result obtained from the method of claim 1 to a remote location.

5. A method comprising transmitting data representing a result obtained from the method of claim 1 to a remote location.

6. A method comprising receiving a result obtained from a method of claim 1 from a remote location.

7. The method of claim 1, wherein said applying at least one algorithm to estimate and remove comprises gradient analysis and filtering of the inputted signals.

8. The method of claim 1, wherein said applying at least one algorithm to estimate and remove includes entering at least one blocking factor to remove blocking effects.

9. The method of claim 8, further comprising employing generalized response-surface methodology to approximate global gradient effects of the inputted data.

10. The method of claim 3, wherein said de-trending removes all low frequency and block patterns from the inputted data.

11. The method of claim 3, wherein said de-trending is carried out by a harmonic model plus shift effects.

12. The method of claim 3, wherein said de-trending comprises use of a second-order polynomial plus shift factors.

13. The method of claim 12, wherein said de-trending further comprises use of a statistical predictor method using similarity transforms.

14. The method of claim 3, further comprising optimizing said de-trending by least squares regression.

15. The method of claim 1, wherein said non-biological distortions are selected from at least one of the group consisting of array patterns, channel bias and build bias.

16. The method of claim 1, wherein said non biological distortions include array patterns, channel bias and build bias.

17. The method of claim 1, wherein said inputting signals comprises inputting signals through at least two channels, each channel inputting a distinct set of signals generated from reading an array containing biological data.

18. The method of claim 17, further comprising comparing outputted results from the at least two channels; and de-warping the outputted results based on error properties of the outputted results.

19. A method comprising forwarding a result obtained from the method of claim 18 to a remote location.

20. A method comprising transmitting data representing a result obtained from the method of claim 18 to a remote location.

21. A method comprising receiving a result obtained from a method of claim 18 from a remote location.

22. The method of claim 1, further comprising assessing the analytical performance of the array using at least one of the metrics selected from the group consisting of accuracy, precision, standard deviation of signal response, coefficient of variation of signal response, comparative precision, concordance correlation, minimum detectable fold change, analytical sensitivity, threshold, limit of detectable response, limit of detection, limit of quantifiable signal response, limit of quantitation, linearity, dynamic range, linear dynamic range and signal response range.

23. The method of claim 1, further comprising assessing the quality of the array using at least one of the metrics selected from the group consisting of statistical calibration, asymmetry in signal response, mean signal response, standard deviation in signal response, coefficient of variation in signal response, skewness, kurtosis and control charting.

24. A computer-implemented method of evaluating profiles of multi-variable data values, said method comprising the steps of:
training on a training set of profiles having been previously evaluated;
determining a computer functional relationship between the training profiles and values assigned to the respective training profiles during the previous evaluation; and
applying the computer functional relationship to one or more profiles not belonging to the training set to generate evaluation values for the one or more profiles not belonging to the training set.

25. The method of claim 24, wherein the training set of profiles have been previously evaluated by one or more human inspectors.

26. A method comprising forwarding a result obtained from the method of claim 24 to a remote location.

27. A method comprising transmitting data representing a result obtained from the method of claim 24 to a remote location.

28. A method comprising receiving a result obtained from a method of claim 24 from a remote location.

29. The method of claim 24, wherein each of said profiles of said training set and each of said profiles not belonging to the training set comprises data characterizing a microarray.

30. The method of claim 24, wherein said multi-variable data values comprise metrics generated from analyzing signals generated from reading a microarray.

31. The method of claim 30, wherein said metrics comprise at least one of an estimated parameter from de-trending, an estimated parameter from de-warping, a delta metric, an accuracy metric, a precision metric, an analytical sensitivity metric, a linearity metric, a dynamic and linear dynamic range metric or a statistical calibration.

32. The method of claim 24, wherein said training comprises de-trending the training set of profiles.

33. The method of claim 32, wherein said training further comprises de-warping the training set of profiles.

34. The method of claim 32, wherein said training further comprises creating metrics representative of the de-trended profiles.

35. The method of claim 33, wherein said training further comprises creating metrics representative of the de-trended profiles after said de-trending, and creating metrics representative of the de-warped profiles after said de-warping

36. The method of claim 24, wherein said determining a computer function relationship comprises application of an initial model and development of a more complex model to determine the computer functional relationship.

37. The method of claim 36, wherein the initial model comprises Model Zero.

38. The method of claim 36, wherein the more complex model comprises a predictor-corrector model.

39. The method of claim 24, wherein said evaluation values comprises classification and quality scoring values.

40. The method of claim 39, wherein said classification and quality scoring values comprise pass, fail and marginal.

41. A method of automatically classifying and quality scoring microarrays containing biological data, said method comprising the steps of:
training on a training set of microarrays having been previously classified and scored by one or more human inspectors;
determining a computer functional relationship between the training set and classification and scoring values assigned to the respective training microarrays in the training set by the one or more human inspectors; and
applying the computer functional relationship to one or more microarrays containing biological data and not belonging to the training set, and automatically classifying and scoring the one or more microarrays not belonging to the training set, based on the computer functional relationship.

42. The method of claim 41, wherein said training comprises:
de-trending each microarray in the training set;
creating metrics representative of each microarray after de-trending;
de-warping each microarray in the training set;
creating metrics representative of each microarray after de-warping; and
generating a profile for each microarray in the training set, wherein each profile contains said metrics after de-trending and de-warping; and
wherein said determining a computer functional relationship comprises:
applying an initial model and developing a more complex model to determine the computer functional relationship between said profiles and said classification and quality scores having been previously assigned to said training set.

43. The method of claim 41, wherein said applying the computer functional relationship to one or more microarrays containing biological data and note belonging to the training set, and automatically classifying and scoring the microarrays not belonging to the training set, based on the computer functional relationship comprises:
de-trending each microarray not belonging to the training set;
creating metrics representative of each microarray not belonging to the training set, after de-trending;
de-warping each microarray not belonging to the training set;
creating metrics representative of each microarray not belonging to the training set, after de-warping; and
generating a profile for each microarray not belonging to the training set, wherein each profile contains said metrics after de-trending and de-warping; and
applying said computer functional relationship to said profiles characterizing said microarrays not belonging to the training set, to automatically classify and quality score said microarrays not belonging to the training set.

44. A system for removing nuisance distortions from array data, said system comprising:
means for inputting signals generated from reading an array containing biological data;
means for applying at least one algorithm to the inputted signals to estimate and remove at least one nuisance distortion from the signals representing the array data; and
means for outputting signals representative of the biological data after removal of said at least one nuisance distortion.

45. A computer readable medium carrying one or more sequences of instructions for removing nuisance distortions from array data, wherein execution of one or more sequences of instructions by one or more processors causes the one or more processors to perform the steps of:
inputting signals generated from reading an array containing biological data;
applying at least one algorithm to the inputted signals to estimate and remove at least one nuisance distortion from the signals representing the array data; and
outputting signals representative of the biological data after removal of said at least one nuisance distortion.

46. A system for evaluating profiles of multi-variable data values, said system comprising:
means for training on a training set of profiles having been previously evaluated;
means for determining a computer functional relationship between the training profiles and values assigned to the respective training profiles during the previous evaluation; and
means for applying the computer functional relationship to one or more profiles not belonging to the training set to generate evaluation values for the one or more profiles not belonging to the training set.

47. A computer readable medium carrying one or more sequences of instructions for evaluating profiles of multi-variable data values, wherein execution of one or more sequences of instructions by one or more processors causes the one or more processors to perform the steps of:
training on a training set of profiles having been previously evaluated;
determining a computer functional relationship between the training profiles and values assigned to the respective training profiles during the previous evaluation; and
applying the computer functional relationship to one or more profiles not belonging to the training set to generate evaluation values for the one or more profiles not belonging to the training set.

48. A system for automatically classifying and quality scoring microarrays containing biological data, said system comprising:
means for training on a training set of microarrays having been previously classified and scored;
means for determining a computer functional relationship between the training set and classification and scoring values assigned to the respective training microarrays in the training set; and
means for applying the computer functional relationship to one or more microarrays containing biological data and not belonging to the training set, and automatically classifying and scoring the microarrays not belonging to the training set, based on the computer functional relationship.

49. A computer readable medium carrying one or more sequences of instructions for automatically classifying and quality scoring microarrays, wherein execution of one or more sequences of instructions by one or more processors causes the one or more processors to perform the steps of:
training on a training set of microarrays having been previously classified and scored;
determining a computer functional relationship between the training set and classification and scoring values assigned to the respective training microarrays in the training set; and
applying the computer functional relationship to one or more microarrays containing biological data and not belonging to the training set, and automatically classifying and scoring the microarrays not belonging to the training set, based on the computer functional relationship.
